(19) United States
(12) Patent Application Publication
(10) Pub. No.: US 2008/0157157 A1
(43) Pub. Date: Jul. 3, 2008

(54) SEMICONDUCTOR INTEGRATED CIRCUIT DEVICE

(76) Inventors: Osamu TONOMURA, Kokubunji (JP); Hiroshi MIKI, Tokyo (JP); Tomoko SEKIGUCHI, Hino (JP); Kenichi TAKEDA, Tokorozawa (JP)

Correspondence Address: MILES & STOCKBRIDGE PC, 1751 PINNACLE DRIVE, SUITE 500, MCLEAN, VA, 22102-3833, US

(21) Appl. No.: 11/940,667

(22) Filed: Nov. 15, 2007

(30) Foreign Application Priority Data
Dec. 27, 2006 (JP) 2006-351721

(51) Int. Cl. H01L 29/94

(52) U.S. Cl. 257/300; 257/E29.345

(57) ABSTRACT

A DRAM capacitor uses ruthenium or ruthenium oxide as an upper electrode and hafnium dioxide or zirconium oxide as an insulation layer. The DRAM capacitor is intended to suppress diffusion of ruthenium, etc. into hafnium dioxide. Tantalum pentoxide or niobium oxide having a higher permittivity than that of the insulation layer is inserted as a cap insulation layer to the boundary between the upper electrode of ruthenium or ruthenium oxide and the insulation layer of hafnium dioxide or zirconium oxide to thereby suppress diffusion of ruthenium, etc. into hafnium dioxide, etc.

### CLAIM OF PRIORITY

The present application claims priority from Japanese application JP 2006-351721 filed on Dec. 27, 2006, the content of which is hereby incorporated by reference into this application.

### BACKGROUND OF THE INVENTION

1. Field of the Invention

The present invention relates to a constitution of a capacitor of a DRAM (Dynamic Random Access Memory) which is a memory for storing information by accumulating charges in the capacitor.

2. Description of the Related Art

Refinement of semiconductor devices has proceeded with an aim of improving the performance. In the memory cell of DRAM, while the occupied area thereto has been decreased along with refinement, a capacitor formed in the memory cell is required to have a constant capacitance irrespective of generations in order to prevent reading failure. Accordingly, increase in the density of the capacitance is demanded for the development of capacitors in the next generation. To make the density of the capacitance higher, the electrode area has been increased and the thickness of the insulation layer has been reduced. While the electrode structure was planar so far, three dimensional techniques have been adopted for increasing the electrode area in a memory cell having a predetermined area. At present, capacitors of stack type and trench type are predominant. Both of them are cylindrical in the capacitor structure, and an aspect ratio that represents the ratio of the height to the diameter of the cylinder is as large as 20 or more, and fabrication thereof has become difficult more and more. Further, in the generation of using MIS type capacitors in which polysilicon is used for a lower electrode, a surface roughening technique for polysilicon has been used to increase the effective area of the electrode. However, there is a limit also for the extent of the area that can be increased by the surface roughening technique for polysilicon. Accordingly, decrease of the thickness for the insulation layer has been performed concurrently.

Decrease in the thickness of the insulation layer results in a problem of increase a leak current that flows passing through the insulation layer. While a refreshing operation of accumulating charges again in the capacitor is required for retaining information in DRAM, the refreshing operation has to be performed frequently as the leak current is higher. As a result, power consumption is increased. To suppress the increase of the power consumption, the leak current density has to be suppressed to about to 1×10⁻⁷ A/cm² or less irrespective of the generation.

While silicon dioxide has been used as the material for the insulation layer, if an equivalent oxide layer thickness which is a layer thickness converted from the capacitance is decreased to 6 nm or less assuming that a relative permittivity is 3.9, a direct tunneling leakage current becomes remarkable. For the direct tunneling leakage current the amount of leak current, is substantially determined by the physical layer thickness of the insulation layer and when the layer thickness is decreased by 1 nm, the leak current increases by the order of a digit. Therefore, in the state where the direct tunneling leakage current is remarkable, it is difficult due to the variation of the leak current caused by the variation of the layer thickness that all the capacitors of a memory array is adapted to fall within a required leak current specification. That is, it is essential to suppress the direct tunneling leakage current.

Application of a high permittivity insulation layer has been considered as a method of attaining both increase in the capacitance by the decrease of the equivalent current oxide layer thickness and suppression of the direct tunneling leakage current due to increase in the physical thickness of layer. Since hafnium dioxide as a high permittivity insulation layer material has a relative permittivity of about 20, the physical thickness of layer can be made to 10 nm or more even when the equivalent oxide layer thickness is 2.0 nm, which is effective for the suppression of the direct tunneling leakage current. Further, in the generation of using a high permittivity insulation layers of hafnium dioxide, application of an MIM type capacitor with no depletion capacitance and advantageous for the decrease in the layer thickness is effective. As the material for the lower electrode used therein, titanium nitride having a high DRAM process affinity is most prominent. It has been known that hafnium dioxide forms a good boundary with the lower electrode of titanium nitride and this is a prominent insulation layer material.

Meanwhile, a capacitor for use in DRAM using hafnium dioxide as the insulation material and titanium nitride as the electrode has been reported in “A Robust Alternative for the DRAM Capacitor of 50 nm Generation”, IEEE, 2004 by Nongseo-Lee, et al. Sansei Denshi (Non-Patent Document 1). In this report, Ru/Ta₂O₅/HfO₂/TiN has been studied as a capacitor with a premise of ensuring Toxeq.

### SUMMARY OF THE INVENTION

However, in the case of using an insulation layer having a high permittivity as in hafnium dioxide described above, increase in the leak current due to the deterioration of the insulating performance results in a problem. As a trend of the material physical property, since the band gap is narrower as the permittivity becomes higher, Fowler-Nordheim leak current that undergoes the effect for the height of the barrier may be increased. Then, applying an electrode having a large work function is considered as a method of relatively increasing the barrier height of the electrode and the insulation layer. For example, ruthenium has a work function of about 4.8 eV which is higher compared with a work function of 4.2 eV of titanium nitride as an electrode material used generally at present, and thereby it is possible to increase the barrier height.

However, at the current level of DRAM technique, no practical characteristic can be obtained unless combination of the insulation layer and the electrode for the capacitor is investigated sufficiently.

For various constituent elements of a capacitor for use in DRAM, the result of study as a base of the present invention is to be shown and then the gist of the invention is to be disclosed.

At first, evaluation was made on a capacitor having an upper electrode using ruthenium and an insulation layer of hafnium dioxide as typical materials. To apply the capacitor of the structure to DRAM products, at first, the profile of elements in the direction of the depth at the boundary between each of the materials has to be steep. The energy loss due to generation of heat by current has to be minimized by lowering the density of impurities contained in the metal as the electrode and improving the electric conductivity. Further, it is necessary for the insulation layer to minimize impurities such as metal elements thereby preventing occurrence of the density of state in the band gap, which may cause increase in the leak current. Inter-diffusion due to stacking or diffusion of an element constituting one material to the other material is considered most plausibility as the possibility for the intrusion of impurities to the materials each other. As the first condition for obtaining required performance in view of the equivalent oxide layer thickness, the leak current, or the reliability of a capacitor, it is generally essential not to cause diffusion between each of the materials. In view of the foregoings, the problem to be solved by the invention is to form a capacitor with no diffusion or inter-diffusion and having a boundary in which the element profile is steep in the direction of the depth in a structure of using an insulation layer of hafnium dioxide and an upper electrode of ruthenium.

The gist of the invention resides in a semiconductor integrated circuit device, comprising, above a semiconductor substrate: a plurality of word lines; a plurality of bit lines; and memory cells each comprising a memory selecting transistor disposed at a predetermined intersection between the plurality of word lines and the plurality of bit lines, and an information storing capacitor connected electrically in series with the memory selecting transistor; wherein the information storing capacitor has a second electrode, a capacitor insulation layer deposited on the second electrode, a cap insulation layer deposited on the cap capacitor insulation layer, and a first electrode deposited on the cap insulation layer. Then, the first electrode is formed of at least one element selected from ruthenium and ruthenium oxide, the insulation layer is formed of at least one element selected from the group consisting of hafnium oxide, yttrium-added hafnium oxide, and zirconium oxide, and the second electrode is formed of at least one element selected from the group consisting of titanium nitride, titanium, tantalum nitride, tantalum, tungsten nitride, tungsten, phosphorus-doped polysilicon, gold, silver, copper, and platinum.

The second electrode is usually disposed on the side of the semiconductor substrate and referred to as the lower electrode. The first electrode is usually disposed on the side opposite to the semiconductor substrate relative to the capacitor insulation layer and is usually referred to as an upper electrode.

Further, the cap insulation layer is formed of at least one member selected from tantalum oxide and niobium oxide having a higher permittivity than the insulation layer and the thickness is defined such that a continuous layer is formed. Preferably, the thickness of the cap insulation layer is 2 nm or more and 2 nm or less. Further, the band gap is smaller than that of the capacitor insulation layer. The cap insulation layer is interposed between the insulation layer and the upper electrode to have a reduction in an smaller amount of the conduction band offset of the insulation layer compared with the case of using aluminum as the cap insulation layer.

Further, the cap insulation layer is usually formed above the capacitor insulation layer with reference to the semiconductor substrate but the relation of stacking may be reversed.

According to the invention, it is possible to attain lower power consumption, larger capacitance, and higher operation speed of a semiconductor integrated circuit device having a DRAM memory. It is particularly useful in a semiconductor integrated circuit device using DRAM, and having a high density integrated memory circuit and a logic hybrid memory in which a memory circuit and a logic circuit are disposed on one identical semiconductor substrate.

### BRIEF DESCRIPTION OF THE DRAWINGS

Other objects and advantages of the invention will become apparent from the following description of embodiments with reference to the accompanying drawings in which:

FIG. 1 is a graph showing a permittivity necessary for obtaining a desired physical thickness of insulation layer at a predetermined equivalent oxide layer thickness;

FIG. 2 is a graph showing reported values for relative permittivity and band gap of insulative layer materials for use in semiconductors;

FIG. 3 is a graph showing the dependence of an equivalent oxide layer thickness on the ruthenium deposition temperature;

FIG. 4 is a graph showing the dependence of an leak current density on the ruthenium deposition temperature;

FIG. 5A is a graph showing the dependence of the percentage of contained elements on the depth of specimens at an Ru/HfO₂ boundary;

FIG. 5B is a graph showing the dependence of the percentage of contained elements on the depth of specimens at an Ru/HfO₂ boundary;

FIG. 5C is a graph showing the dependence of the percentage of contained elements on the depth of specimens at an Ru/HfO₂ boundary;

FIG. 5D is a graph showing the dependence of the percentage of contained elements on the depth of specimens at an Ru/HfO₂ boundary;

FIG. 6 is a graph showing the dependence of the equivalent oxide layer thickness on the insulation layer thickness of a cap layer of tantalum pentoxide;

FIG. 7 is a graph showing the dependence of the leak current density on insulation layer thickness of a cap layer of tantalum pentoxide;

FIG. 8 is a graph showing the dependence of the equivalent oxide layer thickness on the insulation layer thickness of an alumina cap layer;

FIG. 9 is a graph showing the dependence of the leak current density on the insulation layer thickness of an alumina cap layer;

FIG. 10 is a graph showing the dependence of the percentage of contained elements on the specimen depth in the case of using a cap insulation layer of tantalum pentoxide;

FIG. 11A is a graph showing the dependence of a valence band waveform on the layer thickness of tantalum pentoxide in Ru/HfO₂ stack;

FIG. 11B is a graph showing the dependence of a valence band waveform on the layer thickness of tantalum pentoxide in Ru/Ta₂O₅/HfO₂ stack;

FIG. 11C is a graph showing the dependence of a valence band waveform on the layer thickness of tantalum pentoxide in Ru/Ta₂O₅/HfO₂ stack;

FIG. 11D is a graph showing the dependence of a valence band waveform on the layer thickness of tantalum pentoxide in Ru/Ta₂O₅/HfO₂ stack;

FIG. 12A is a schematic view of an electron state and a specimen structure in a Ta₂O₅ layer (layer thickness: less than 2 nm);

FIG. 12B is a schematic view of an electron state and a specimen structure in a Ta₂O₅ layer (layer thickness: 2 nm or more);

FIG. 13 is a graph showing an ols peak waveform attributable to hafnium dioxide;

FIG. 14 is a graph showing an Ta4f peak waveform attributable to tantalum pentoxide;

FIG. 15 is a view showing the dependence of a valence band offset amount on the cap insulative layer thickness;

FIG. 16A is a graph showing the dependence of an Hf4f peak waveform on a cap insulation layer thickness in the case where the cap insulation layer is Ta₂O₅;

FIG. 16B is a graph showing the dependence of an Hf4f peak waveform on a cap insulation layer thickness in the case where the cap insulation layer is Al₂O₃;

FIG. 17 is a graph showing the dependence of an Hf4f peak shift on a cap insulation layer thickness;

FIG. 18A is a band diagram when a cap insulation layer of Ta₂O₅ is inserted by 3 nm;

FIG. 18B is a band diagram when a cap insulation layer of Al₂O₃ is inserted by 3 nm;

FIG. 19 is a view showing the dependence of an obtained equivalent oxide layer thickness on a cap insulation layer thickness;

FIG. 20 is a graph showing a band gap, conduction band offset, and a relative permittivity of insulation layer materials;

FIG. 21A is a view showing a band structure of a capacitor having a cap insulation layer;

FIG. 21B is a view showing a band structure of a capacitor having a cap insulation layer;

FIG. 22 is a cross sectional view near a memory cell shown in the order of manufacturing steps for a DRAM memory cell exemplified in Embodiment 1;

FIG. 23 is a cross sectional view near a memory cell shown in the order of manufacturing steps for a DRAM memory cell exemplified in Embodiment 1;

FIG. 24 is a cross sectional view near a memory cell shown in the order of manufacturing steps for a DRAM memory cell exemplified in Embodiment 1;

FIG. 25 is a cross sectional view near a memory cell shown in the order of manufacturing steps for a DRAM memory cell exemplified in Embodiment 1;

FIG. 26 is a cross sectional view near a memory cell shown in the order of manufacturing steps for a DRAM memory cell exemplified in Embodiment 1;

FIG. 27 is a cross sectional view near a memory cell shown in the order of manufacturing steps for a DRAM memory cell exemplified in Embodiment 1;

FIG. 28 is a cross sectional view near a memory cell shown in the order of manufacturing steps for a DRAM memory cell exemplified in Embodiment 1;

FIG. 29 is a cross sectional view near a memory cell shown in the order of manufacturing steps for a DRAM memory cell exemplified in Embodiment 1;

FIG. 30 is a cross sectional view near a memory cell shown in the order of manufacturing steps for a DRAM memory cell exemplified in Embodiment 1;

FIG. 31 is a cross sectional view near a memory cell shown in the order of manufacturing steps for a DRAM memory cell exemplified in Embodiment 1;

FIG. 32 is a cross sectional view near a memory cell shown in the order of manufacturing steps for a DRAM memory cell exemplified in Embodiment 2;

FIG. 33 is a cross sectional view near a memory cell shown in the order of manufacturing steps for a DRAM memory cell exemplified in Embodiment 2;

FIG. 34 is a cross sectional view near a memory cell shown in the order of manufacturing steps for a DRAM memory cell exemplified in Embodiment 2;

FIG. 35 is a cross sectional view near a memory cell shown in the order of manufacturing steps for a DRAM memory cell exemplified in Embodiment 2;

FIG. 36 is a cross sectional view near a memory cell shown in the order of manufacturing steps for a DRAM memory cell exemplified in Embodiment 2;

FIG. 37 is a cross sectional view near a memory cell shown in the order of manufacturing steps for a DRAM memory cell exemplified in Embodiment 2;

FIG. 38 is a cross sectional view near a memory cell shown in the order of manufacturing steps for a DRAM memory cell exemplified in Embodiment 2;

FIG. 39 is a cross sectional view near a memory cell shown in the order of manufacturing steps for a DRAM memory cell exemplified in Embodiment 2;

FIG. 40 is a cross sectional view near a memory cell shown in the order of manufacturing steps for a DRAM memory cell exemplified in Embodiment 2;

FIG. 41 is a cross sectional view near a memory cell shown in the order of manufacturing steps for a DRAM memory cell exemplified in Embodiment 2; and

FIG. 42 is an equivalent circuit diagram for a DRAM in Embodiment 1.

### DESCRIPTION OF THE PREFERRED EMBODIMENT

### Embodiment 1

As described above, in the capacitor of the invention, a first electrode (upper electrode) uses one of members of ruthenium and ruthenium oxide and a second electrode (lower electrode) uses at least one element selected from the group consisting of titanium nitride, titanium, tantalum nitride, tantalum, tungsten nitride, tungsten, phosphorus-doped polysilicon, gold, silver, cupper, and platinum. Further, on the premise for the selection of the first and the second electrode materials, a capacitor insulation layer and a corresponding cap insulation layer were studied. Since the group of materials for the second electrode are those known so far, detailed descriptions therefor are to be omitted. The thickness for each of the members is as described below. The first electrode (upper electrode) is selected within a range from 5 nm to 30 nm, the second electrode (lower electrode) is selected within a range from 5 nm to 30 nm, and the capacitor insulation layer is selected within a range from 3 nm to 10 nm.

This embodiment at first illustrates a typical example of using ruthenium for the first (upper) electrode, titanium nitride for the second (lower) electrode, hafnium oxide (more specifically hafnium dioxide here and hereinafter) for the insulation layer, and tantalum oxide for the second insulation layer (cap insulation layer). Other materials are to be referred to optionally.

The outline for the description regarding this embodiment using specific data is as described below.

(1) At first, as a premise, the first electrode of ruthenium has a large work function and is preferred for suppressing the FN tunneling leakage current in a capacitor. This is identical also for ruthenium oxide.

(2) For the capacitor insulation layer, a physical thickness of layer of 6 nm or more is required for suppressing the direct tunneling leakage current. However, along with proceeding of the generation, it is necessary to increase the capacitance value of a capacitor according to the decrease of the layer thickness. Then, it is necessary to apply a high permittivity material capable of obtaining a smaller equivalent oxide layer thickness relative to a physical thickness of layer for a capacitor insulation layer. On the other hand, when a material with high permittivity is used, the band gap tends to be lowered to cause increase in the leak current. In view of the practical aspects of the four factors, hafnium dioxide is most preferred as the material for the insulation layer. Further, with the same reason as described above, examples of the material for the insulation layer include yttrium-added hafnium oxide or zirconium oxide.

(3) However, direct contact ruthenium with hafnium dioxide result in diffusion of ruthenium into hafnium dioxide during manufacturing steps. To prevent the diffusion, it is necessary to interpose a second insulation layer (hereinafter referred to as a cap insulation layer) to the boundary between both of them.

(4) For the cap insulation layer, it is preferred to adopt a material of a higher permittivity than that of the capacitor insulation layer. This is because there are neither increase in the equivalent oxide layer thickness nor loss of capacitance in both of the capacitor insulation layer and the cap insulation layer. In view of the above, the cap insulation layer is preferably formed of tantalum oxide (more specifically, tantalum pentoxide herein and hereinafter), niobium oxide, etc. The thickness is such that it can constitute a continuous layer and has a thickness of 3 nm or less. Practically, the thickness of the cap insulation is 2 nm or more. This is because the lowering amount of the conduction band offset of the insulation layer is small by insertion of the cap insulation layer between the insulation layer and the upper electrode.

Referring to the facts for the items (2) to (4), problems and countermeasures therefor in a capacitor using ruthenium for the first (upper) electrode, titanium nitride for the second (lower) electrode, and hafnium dioxide for the insulation layer are examined below.

<Reason that Hafnium Dioxide is Preferred as the Insulation Layer Material>

It is to be examined that hafnium dioxide is extremely useful for ensuring the equivalent oxide layer thickness and the relative permittivity required at present for the capacitor insulation layer to be served for the DRAM memory. It has been known that hafnium dioxide is promising for the MIM capacitor using titanium nitride for the upper electrode and the lower electrode. In this case each of electrodes is formed of titanium nitride. On the other hand, in the invention, ruthenium or ruthenium oxide is used for the first electrode as one of them. In view of the conditions described above, it is to be explained why hafnium dioxide is preferred.

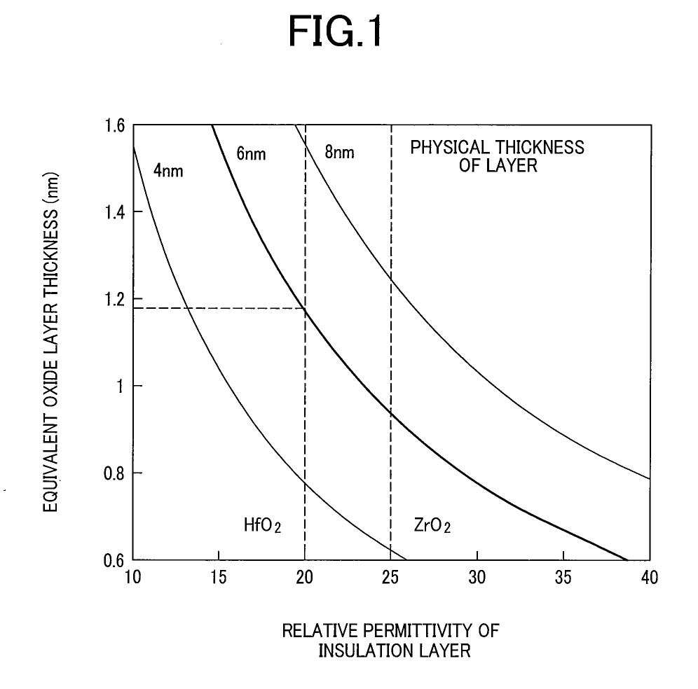

At first, description is to be made to the equivalent oxide layer thickness that can be obtained by using an insulation layer material of a certain permittivity with reference to FIG. 1. In FIG. 1, the abscissa indicates the relative permittivity of insulation layers, and the ordinate represents calculated values for the equivalent oxide thickness obtained in the case of depositing insulation layer materials each having a relative permittivity by a certain physical thickness of layer. The parameter is a physical thickness of an insulation layer. When hafnium dioxide having a permittivity of 20 is deposited as a material for the insulation layer to a physical thickness of layer of 6 nm that can suppress the direct tunneling leakage current, the limit for the decrease of the layer is about 1.2 nm in FIG. 1. The result of calculation in FIG. 1 suggests that the layer thickness in the structure is decreased, the equivalent oxide layer thickness of about 1.2 nm results in a limit for the decrease of layer thickness due to increase in the direct tunneling leakage current. Further, when the physical thickness of layer of hafnium dioxide is decreased to reduce the layer thickness, the Fowler-Nordheim (FN) tunneling leakage current may possibly increase due to decrease in the tunneling barrier of the insulation layer. It is considered that the problem tends to occur, particularly, in the case of using hafnium dioxide at a physical thickness of layer of about 6 nm as a limit for the decrease of the layer thickness.

On the other hand, to suppress the amount of investment and reduce the cost to film deposition apparatus for insulation layers equipped in mass production lines, it is desirable that an identical material be applied for a generation as long as possible. Also in view of the above, in the case where a hafnium dioxide capacitor of an MIM structure using titanium nitride for an upper electrode and a lower electrode reaches a limit for the decrease of the layer thickness due to increase in the FN tunneling leakage current, it is desirable to form the upper electrode using ruthenium having a larger work function than that of titanium nitride. It is considered that the constitution can suppress the FN tunneling leakage current and further develop decrease in the layer thickness. It is also useful to form the upper electrode and the lower electrode with ruthenium.

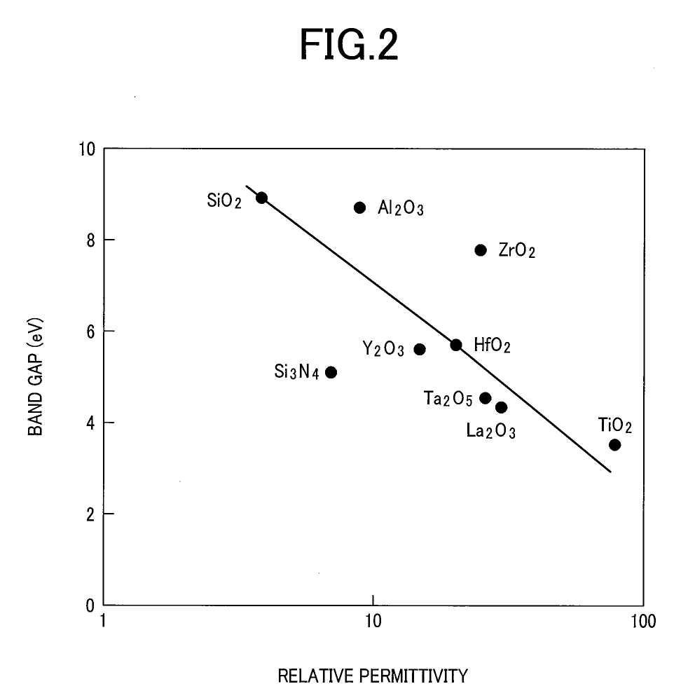

FIG. 2 shows candidates for materials of the insulation layers used for semiconductors. In FIG. 2, the abscissa and the ordinate represent the relative permittivity and band gap, respectively. While higher permittivity is necessary as the generation proceeds, larger band gap is also necessary for suppressing the leak current. However, as can be seen from FIG. 2, it can be seen that the band gap tends to decrease as the relative permittivity increases. That is, using a material having an unnecessarily high relative permittivity may result in a problem in view of the suppression for the leak current by the decrease in the height of the barrier due to the narrowness of the band gap. Accordingly, as the insulation layer used for respective generations, an insulation layer having an appropriate relative permittivity necessary for attaining a demanded equivalent oxide layer thickness is preferred. That is, to obtain the equivalent oxide layer thickness of about 1.2 nm, it can be said that hafnium dioxide is a most appropriate insulation layer as the insulation layer material.

<Problem in the Structure where Ruthenium and Hafnium Dioxide are in Direct Contact with Each Other and Necessity for Cap Insulation Layer>

At present, for memory cell capacitors to be mounted on DRAM, the leak current density has to be restricted to about 10⁻⁷ A/cm² or less. In view of the condition described above, it has been investigated for a capacitor of a structure using ruthenium for the upper electrode, titanium nitride for the lower electrode, and hafnium dioxide for the insulation layer as to what leak current occurs and what is the cause therefor. Then, it has been found that the leak current is caused by diffusion of ruthenium in the electrode into hafnium dioxide of the insulation layer. Then, as a method of suppressing diffusion of ruthenium, insertion of the cap insulation layer to the boundary between ruthenium and hafnium dioxide has been investigated.

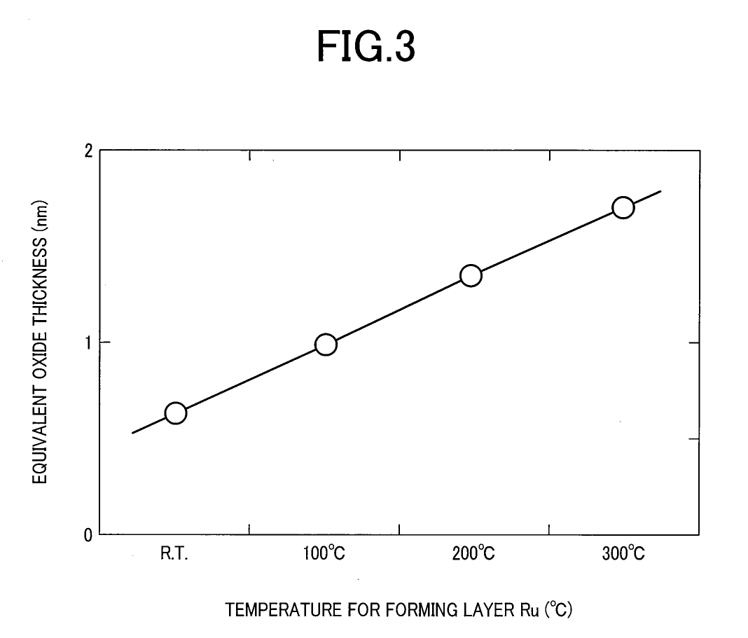

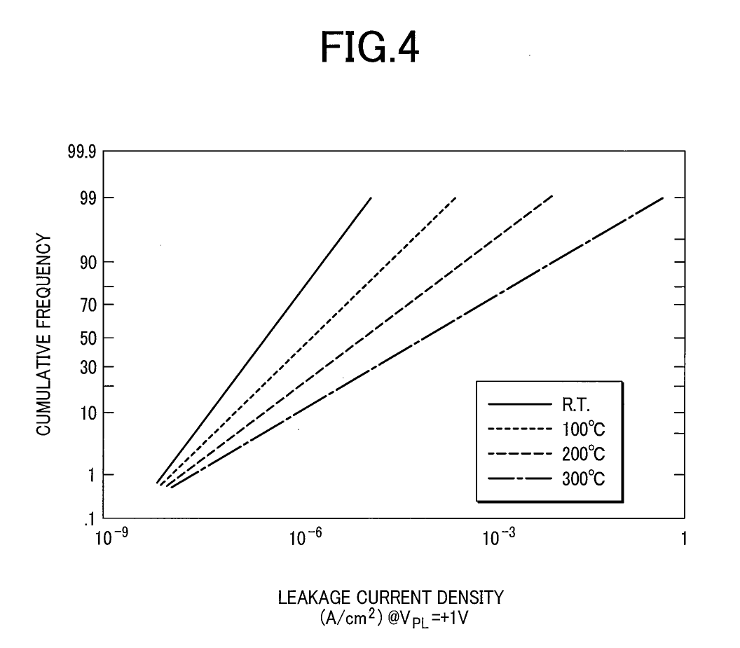

At first, a capacitor of a structure using ruthenium for the upper electrode, titanium nitride for the lower electrode, and hafnium dioxide for the insulation layer was manufactured trially and electric properties and the result of physical analysis are shown. FIG. 3 shows a relation between the film deposition temperature of ruthenium and the equivalent oxide layer thickness of the capacitor (approximate ETO value). The film deposition temperature is at room temperature (R. T), 100° C., 200° C., and 300° C. Titanium nitride was deposited to 30 nm by chemical vapor deposition and hafnium dioxide was deposited to 10 nm by atomic layer deposition, and ruthenium was deposited to 50 nm by sputtering. 50% is present about between 0.5 nm and 2.0 nm, which increases along with increase in the film deposition temperature. Further, FIG. 4 shows a schematic diagram of the cumulative frequency distribution of the leak current density. Capacitors of low leak current density shows about 10⁻⁸ A/cm² to 10⁻⁷ A/cm². However, variation increases along with increase in the film deposition temperature and, at a film deposition temperature of 300° C., a capacitor having a large leak current density shows about 1 A/cm². As described above, the leak current density has to be about 10⁻⁷ A/cm² or less for a memory cell capacitor mounted on DRAM. In view of the above, it can be said that the measured leak current is considerably large.

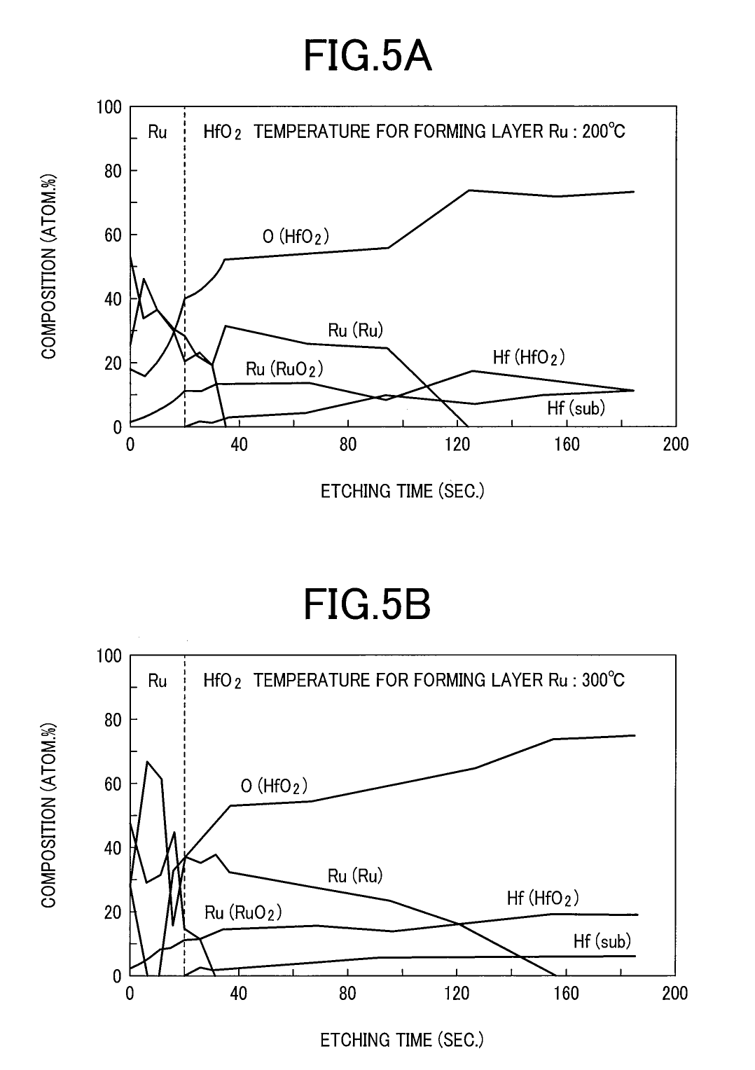

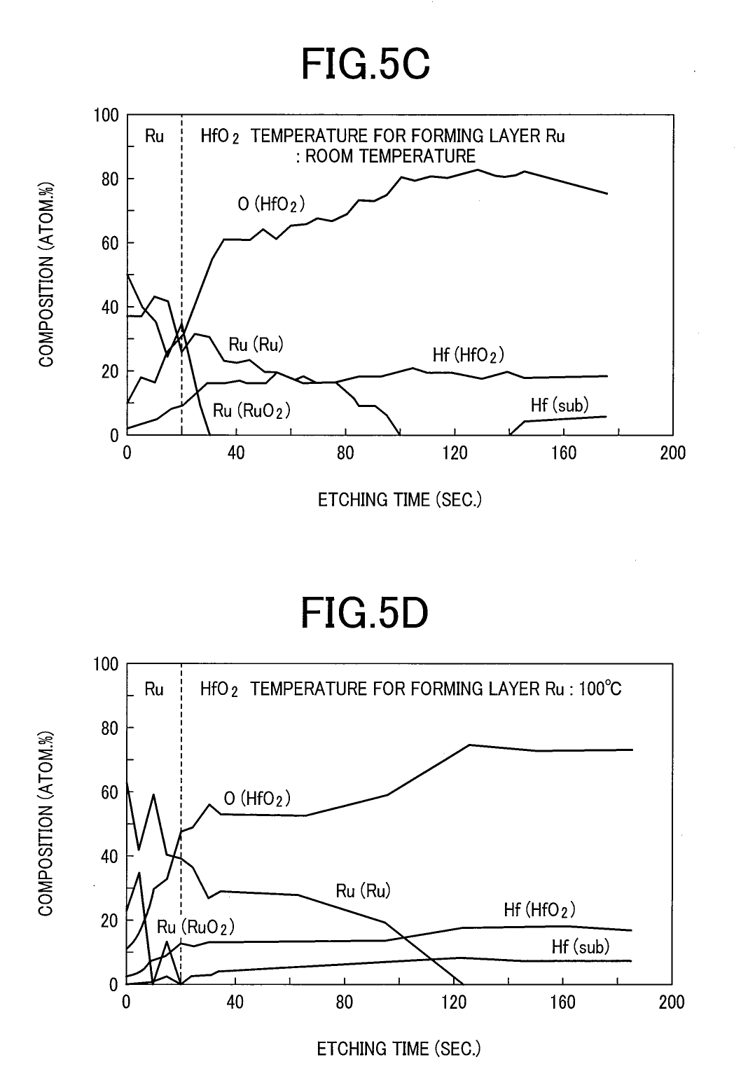

To investigate the cause for the variation of the leak current, analysis by X-ray photoelectronic spectroscopy and etching of specimens by argon ions were conducted alternately to conduct element analysis for each of the specimens in the direction of the depth. FIG. 5A to FIG. 5(D) show the results. Each of the graphs show the result at film deposition temperatures for Ru of 200° C., 300° C., room temperature, and 100° C. Further, the ordinate shows the ratio of each element and each bond expressed by at %, and the abscissa shows the etching time. It should be noted that the etching rate is different depending on the material. It is about at 0.15 nm/sec for ruthenium, and about at 0.05 nm/sec for hafnium dioxide. Detected elements and the state of bonding include five forms, that is, ruthenium attributable to metal ruthenium, ruthenium attributable to ruthenium dioxide, hafnium attributable to hafnium dioxide, sub-peak for hafnium, and oxygen attributable to hafnium dioxide. Near the surface where the argon ion etching time shown by a dotted line is shorter than 20 sec, metal ruthenium is present predominantly. However, at a position deeper than the dotted line, the amount of hafnium attributable to hafnium dioxide and oxygen becomes predominant, which is as expected. However, it should be noted that how the amount of elements near the boundary changes. When a steep boundary without mutual diffusion is formed, it is considered that elements present on the side nearer to the surface than the boundary decrease abruptly near the time shown by the dotted line and it is considered that elements present at a deeper position in the specimen increase abruptly. Actually, ruthenium attributable to ruthenium dioxide decreases abruptly relative to the increase of the argon ion etching time. On the other hand, hafnium and oxygen attributable to hafnium dioxide increase relatively steeply relative to the increase of the argon ion etching time. In contrast, it is expected that ruthenium attributable to metal ruthenium decreases along the slant identical with that of the elements observed so far relative to increase in the argon ion time. However, the slant is actually moderated. For the specimen where the ruthenium film deposition temperature is at a room temperature, at % of ruthenium attributable to ruthenium metal is decreased to 10% or less at about 90 sec. This suggests that ruthenium has diffused in hafnium dioxide. Further, as the ruthenium film deposition time increases, depth in hafnium dioxide where ruthenium attributable to metal ruthenium is detected is increased. As the ruthenium film deposition temperature increases to 100° C., 200° C., and 300° C., the time in which at % of ruthenium attributable to metal ruthenium is decreased to 10% increases as 110 sec, 110 sec, and 140 sec. Due to the fact that elevation of temperature increases the diffusion rate, it is also considered that ruthenium has diffused into hafnium dioxide. Accordingly, to suppress variation of the leak current density shown in FIG. 4, diffusion of ruthenium into hafnium dioxide should be suppressed. Then, insertion of the cap insulation layer to the boundary between ruthenium and hafnium dioxide was investigated as a method of suppressing the diffusion of ruthenium.

### <Reason why Tantalum Oxide is Preferred as the Cap Insulation Layer>

Insertion of the cap insulation layer may cause a worry of increase in the equivalent oxide layer thickness and lowering of the barrier height of hafnium dioxide. Since insertion of the cap insulation layer causes increase in the thickness of the insulation layer, the equivalent oxide layer thickness increases. To prevent diffusion of ruthenium into hafnium dioxide, a cap insulation layer may be inserted by a minimum layer thickness required to be deposited uniformly such that the materials are not in contact with each other.

When this step is performed, the layer thickness is about 2 nm. At 2 nm or less, it is considered that the layer grows in an island shape failing to form a uniform layer and provides no effect of the cap layer even if any of film deposition methods is used. Assuming that a layer is deposited by an identical physical thickness of layer of 2 nm, increase of the equivalent oxide layer thickness can be suppressed more when a material of higher permittivity is used. Accordingly, a material having relatively high permittivity is preferred for the cap insulation layer for suppressing the diffusion of ruthenium into hafnium oxide, as well as for minimizing increase in the equivalent layer thickness of the capacitor. Further, even in the case of inserting a cap insulation layer of 2 nm in the capacitor of this structure, an insulation layer contributing to the Fowler-Nordheim tunneling current or the direct tunneling current is a thick hafnium dioxide. Accordingly, to suppress the leak current, the barrier height between hafnium dioxide and the electrode is important. Inserting the cap insulation layer may influence on the barrier height of hafnium dioxide depending on the material of the cap insulation layer. It is desirable to use the material for the cap insulation layer capable of keeping the barrier height of hafnium dioxide higher even at the insertion of the cap insulation layer. Therefore, in view of the foregoings, the result of investigation of the cap insulation layer is shown and an optimal cap insulation layer is exemplified below.

### <<Comparative Investigation Between Tantalum Pentoxide and Alumina in as the Cap Insulation Layer>>

Tantalum pentoxide and alumina regarded as the candidate were investigated in comparison as the cap insulation layer. While both of them are identical in view of the effect of suppressing the variation of the leak current, the cap insulation layer enables to take a larger height for the barrier of hafnium dioxide. In view of the above, tantalum pentoxide is an optimal material as the cap insulation layer. From the same point of view, niobium oxide is also suitable. Problems for the band structure will be described specifically later.

Candidates for the materials of the cap insulation layer include tantalum pentoxide and alumina. Both of them are materials investigated generally and used for the semiconductor process. Since a technique capable of depositing the materials also for a capacitor at high aspect has been established, tantalum pentoxide and alumina are materials also applicable to DRAM capacitors.

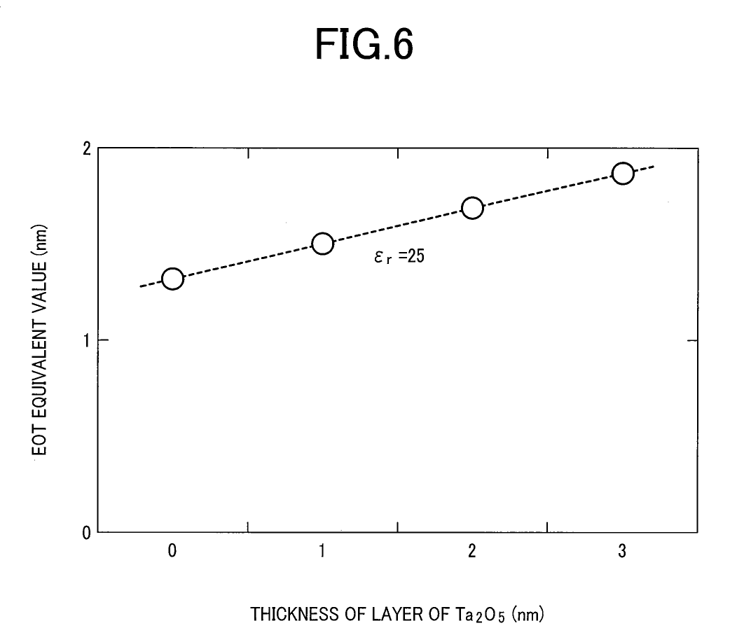

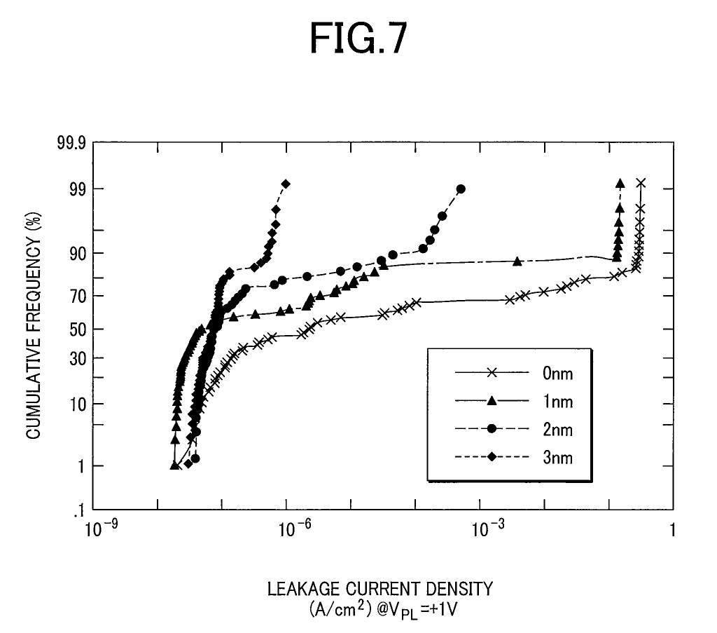

FIG. 6 shows the dependence of the approximate value for the equivalent oxide layer thickness on the cap insulation layer thickness for a capacitor in which tantalum pentoxide is used as the cap insulation layer. Generally, the equivalent oxide layer thickness increases along with increase in the thickness of the cap insulation layer. The relative permittivity determined based on the slant is about 26. Then FIG. 7 shows the dependence of the leak current density on the thickness of the cap insulation layer. It can be seen that the variation of the leak current density decreases drastically as the thickness of the cap insulation layer increases. The leak current density varies by about 4 digits for a 2-nm-thick-tantalum pentoxide and it varies by about 2 digits in the case of 3 nm thickness. That is, it has been found that insertion of the cap insulation layer insertion layer of tantalum pentoxide is extremely effective for suppressing the variation of the leak current density.

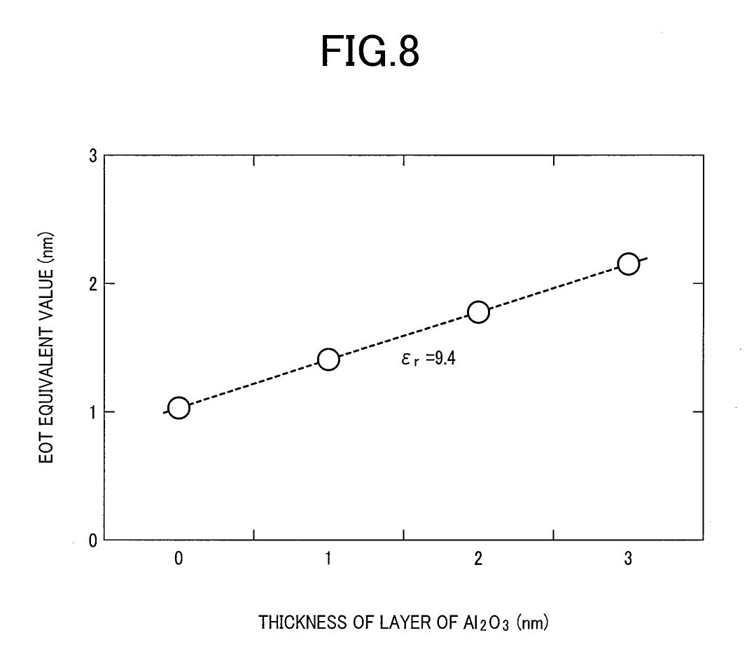

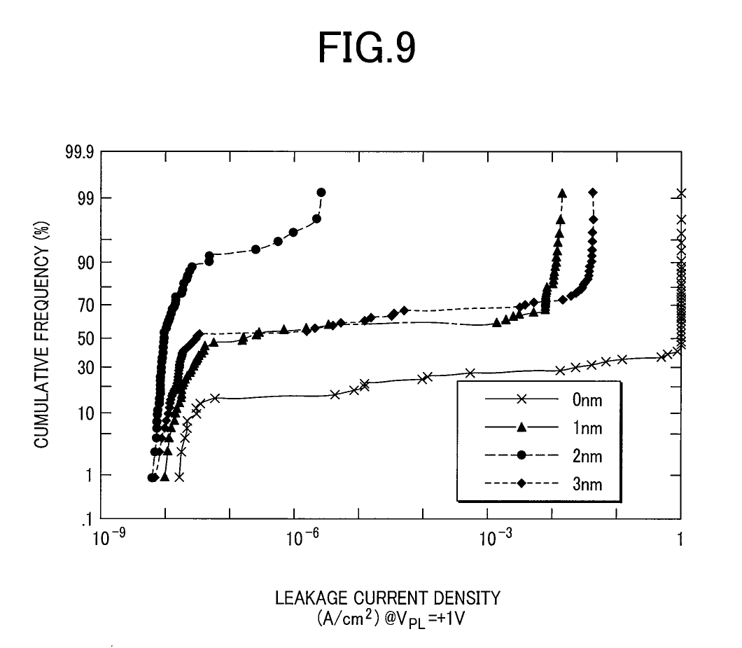

Then, FIG. 8 shows the dependence of the approximate value for the equivalent oxide layer thickness on the thickness of the cap insulation layer in the case of using alumina for the cap insulation layer. The equivalent oxide layer thickness tends to increase along with increase in the layer thickness of alumina. When the relative permittivity was derived based on the slant, it was about 9.4. Comparing with the case of using tantalum pentoxide for the cap insulation layer, it can be seen that the increment for the equivalent oxide layer thickness relative to the physical thickness of the inserted cap insulation layer is large due to the difference of the relative permittivity. When alumina is used for the cap insulation layer, increase in the equivalent oxide layer thickness due to the low relative permittivity was observed actually. Then, FIG. 9 shows the dependence of the leak current density on the thickness of the cap insulation layer. Except for the specimen with an alumina layer thickness of 3 nm, it has been confirmed that the variation of the leak current decreases along with increase in the thickness of the cap insulation layer. The variation of the leak current density of 8 digits in the case of not inserting alumina as the cap insulation layer could be decreased as low as to 3 digits by inserting an alumina layer thickness of 2 nm. That is, it is possible to decrease the variation of the leak current density also by using alumina for the cap insulation layer in the same manner as in the case of inserting tantalum pentoxide.

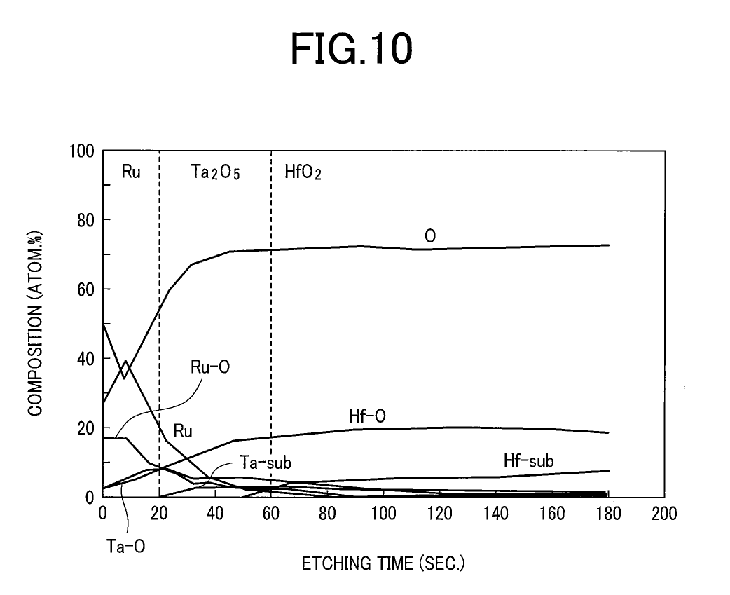

Then, to actually confirm that diffusion of ruthenium into hafnium dioxide is suppressed by inserting the cap insulation layer, an experiment was conducted by combining an X-ray photoelectron spectroscopy and the argon ion etching shown in FIG. 5 by using a specimen where tantalum pentoxide was inserted by 2 nm to the cap insulation layer to acquire depth profile of contained elements. FIG. 10 shows the result. It is considered for the argon ion etching time that etching is conducted for the electrode ruthenium up to 20 sec, for the cap insulation layer of tantalum pentoxide up to 60 sec, and for hafnium dioxide after 60 sec. It can be seen from FIG. 10 that diffusion of ruthenium into hafnium dioxide decreases drastically by the insertion of the 2-nm-thick-tantalum pentoxide cap insulation layer. At the boundary between tantalum pentoxide and hafnium dioxide, at % for ruthenium attributable to metal ruthenium is about 10% or less. That is, it is considered that diffusion of ruthenium into hafnium dioxide was suppressed and the variation of the leak current density was suppressed by using tantalum pentoxide for the cap insulation layer.

From the results described above, it has been found that diffusion of ruthenium into hafnium dioxide is suppressed by using tantalum pentoxide for the cap insulation layer to be inserted between the ruthenium upper electrode and the hafnium dioxide insulation layer.

Considering that the relative permittivity (26) of tantalum pentoxide is higher than the relative permittivity (20) of hafnium dioxide, the insulation layer may be replaced with tantalum pentoxide. However, the method is not effective. This is because tantalum pentoxide forms a steep boundary relative to ruthenium but reacts with titanium nitride when in contact with each other, and thereby a steep boundary is not obtained. That is, it is desired that hafnium dioxide be in contact at the boundary with titanium nitride. In the case of forming the lower electrode with ruthenium, the insulation layer can be formed of a single tantalum pentoxide layer. However, higher technique than that used for the upper electrode is necessary for using ruthenium for the lower electrode. Accordingly, in the generation in which ruthenium is applied for the upper electrode with less technical problem, it is necessary to use titanium nitride which is generally used for the lower electrode.

With a view point as described above, the material to be used for the cap insulation layer material includes niobium oxide. The relative permittivity of the material is about 30 and will have the same effect of the cap layer.

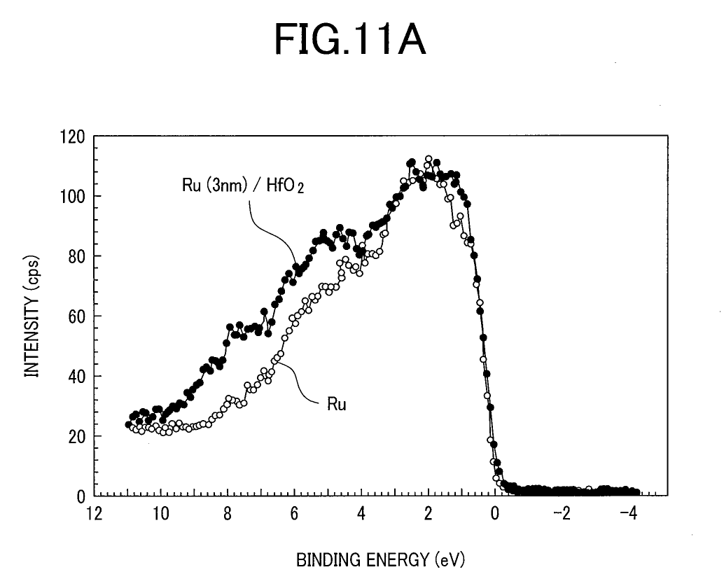

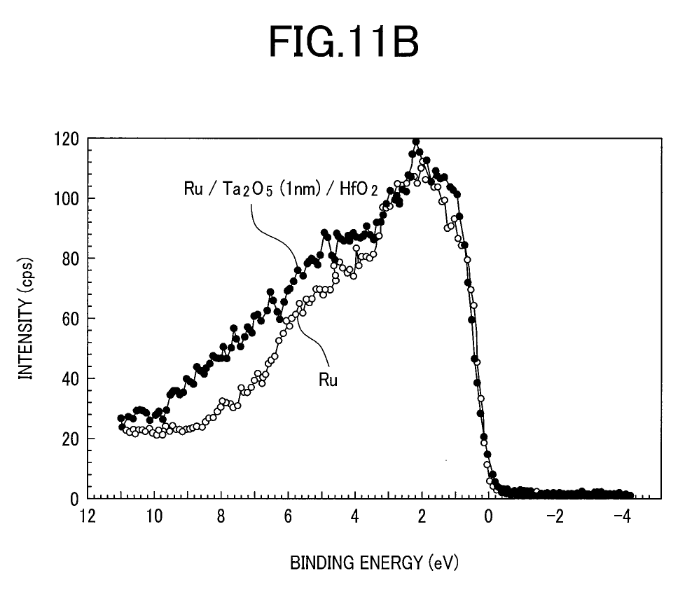

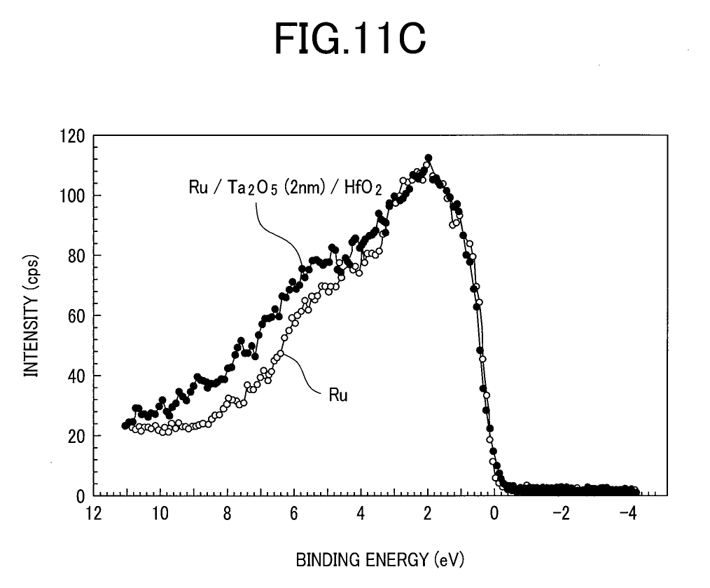

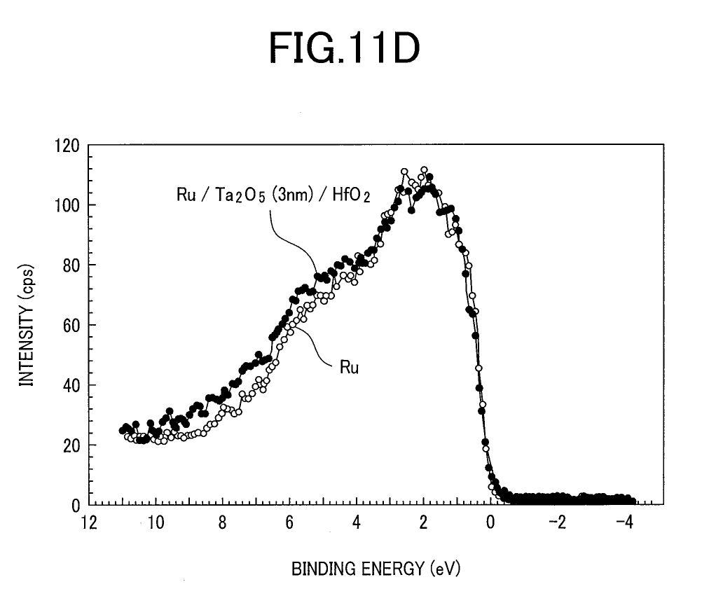

Then, description is to be made to a mechanism of causing variation in the leak current density by the diffusion of ruthenium into hafnium dioxide. Four specimens in which tantalum pentoxide was increased from 0 nm to 3 nm on every 1 nm pitch were analyzed by X-ray photoelectron spectroscopy and FIG. 11A to FIG. 11D show the result of valence band wave forms obtained. Each of the graphs shows, in juxtaposition, a valence band waveform obtained only from ruthenium which was obtained from the analysis of specimens formed by depositing ruthenium to 50 nm. In the valence band waveform, the binding energy 0 eV corresponds to the Fermi energy and shows an energy level deeper than the Fermi energy as the binding energy increases. Further, the intensity of the valence band waveform shows the density of state of electrons at the level. The difference between the valence band waveform only from ruthenium and the waveform where hafnium dioxide and ruthenium are stacked shows the density of state of hafnium dioxide. FIG. 11A is a result for a specimen in which the cap insulation layer is not inserted and a difference of the binding energy is caused about from 2.5 eV. The energy at which the difference starts to form is associated with the upper end of the valence band showing that the valence band offset between the ruthenium Fermi energy and the hafnium dioxide is 2.5 eV. In view of the above, the waveform attributable only to ruthenium and the waveform of a specimen in which hafnium dioxide and tantalum pentoxide of the cap insulation layer are stacked have to overlap at the energy lower than the energy at the upper end of the valence band in any of the specimens. This is because the density of state of the insulation layer is not present since the energy is associated with the band gap of the insulation layer. However, referring to FIG. 11A to FIG. 11D, for the specimen with no cap insulation layer (FIG. 11A) and a specimen with a 1 nm layer (FIG. 11B), a difference of the spectrum is formed between 1 eV-2 eV of the binding energy. On the other hand, the difference is eliminated when the cap insulation layer of tantalum pentoxide is inserted by 2 nm or more. That is, in a specimen with no cap insulation layer in which diffusion of ruthenium into hafnium dioxide is confirmed, some density of state occurs in the band gap of hafnium dioxide. On the other hand, for a specimen with the thickness of the cap insulation layer of tantalum pentoxide of 2 nm or more in which suppression of diffusion is confirmed, it was found that the state in the band cap of hafnium dioxide was eliminated. This result can be explained as described below.

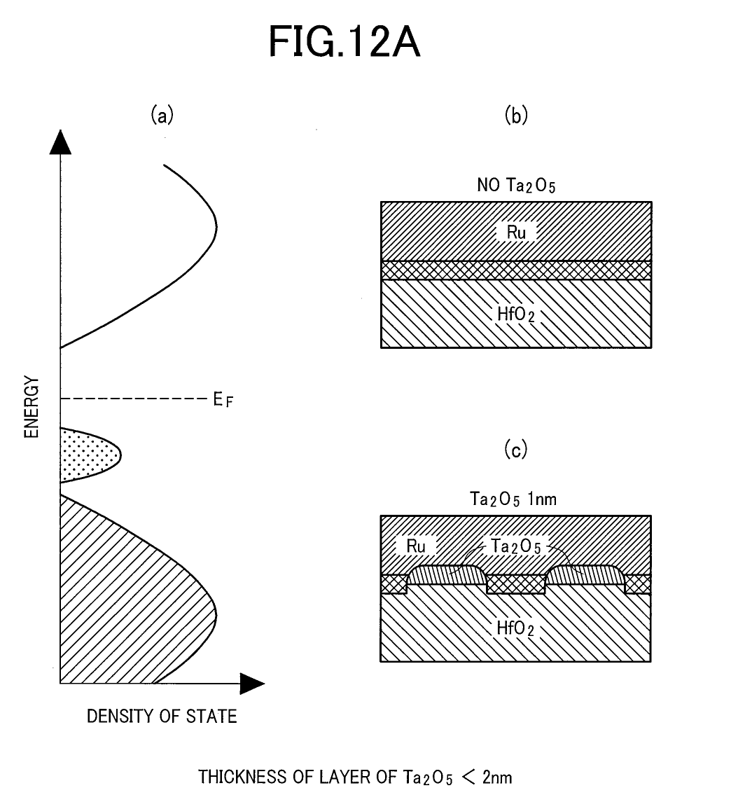

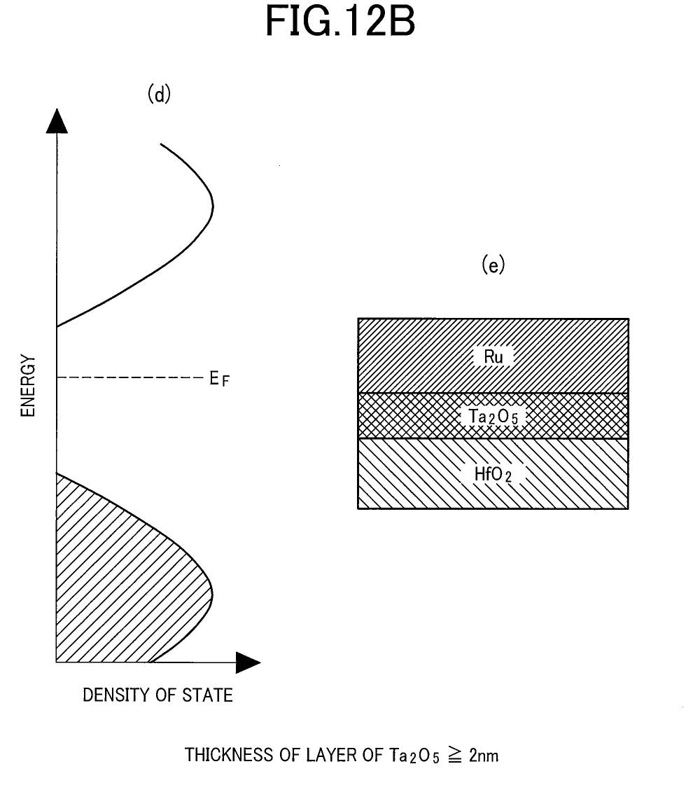

FIG. 12A and FIG. 12B show schematic views for the density of state and a capacitor. In the case where the thickness of the cap insulation layer of tantalum pentoxide is 1 nm or less, that is, in the case of FIG. 12A(b) where tantalum pentoxide is not present, or in the case of FIG. 12A(c) where the uniform film as in the layer of 1 nm is not formed and a portion where ruthenium and hafnium dioxide are in contact with each other is present, it is considered that ruthenium diffuses into hafnium dioxide to form a density of state in the band gap of hafnium dioxide (FIG. 12A(a)). On the other hand, in the case where the thickness of cap insulation layer of tantalum pentoxide is 2 nm or more (FIG. 12B(e)), that is, in the case where ruthenium and hafnium dioxide are separated completely by the cap insulation layer of tantalum pentoxide as a uniform layer, it is considered that diffusion of ruthenium into hafnium dioxide is suppressed, and the density of state does not occur in the band gap of hafnium dioxide (FIG. 12B(a)).

### <<Effect of the Cap Insulation Layer on the Barrier Height of Hafnium Dioxide>>

Then, the effect of the insertion of the cap layer insulation layer on the barrier height of hafnium dioxide is to be described. For the evaluation, a band structure in the case of inserting tantalum pentoxide or alumina by 3 nm to the cap insulation layer was derived by physical analysis.

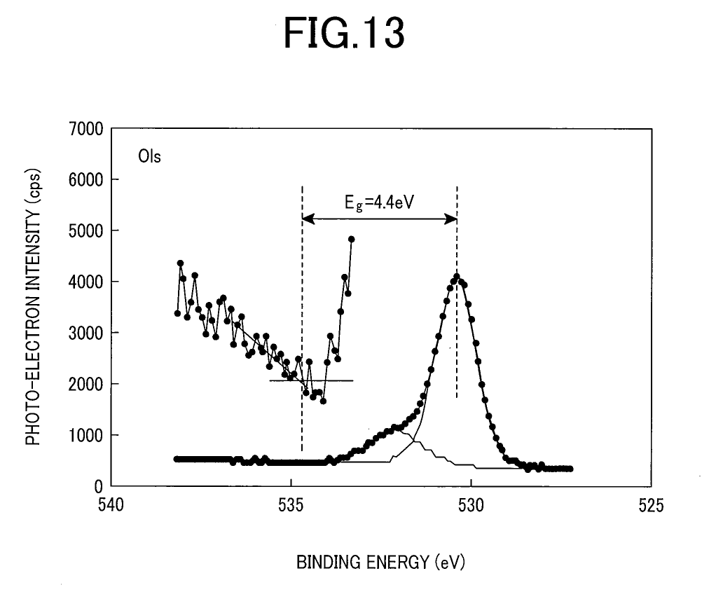

FIG. 13 shows the ols peak waveform attributable to hafnium dioxide. It is known that the difference between the energy for the ols main peak and a rising energy of the loss peak appearing on the high energy side agrees with the band gap of hafnium dioxide. The band gap of hafnium dioxide determined by the method was 4.4 eV. While the value is smaller than the value reported generally, this is because that the deposition method or the like is not optimized. When optimization is conducted, the band gap of hafnium dioxide increases to 6.0 eV.

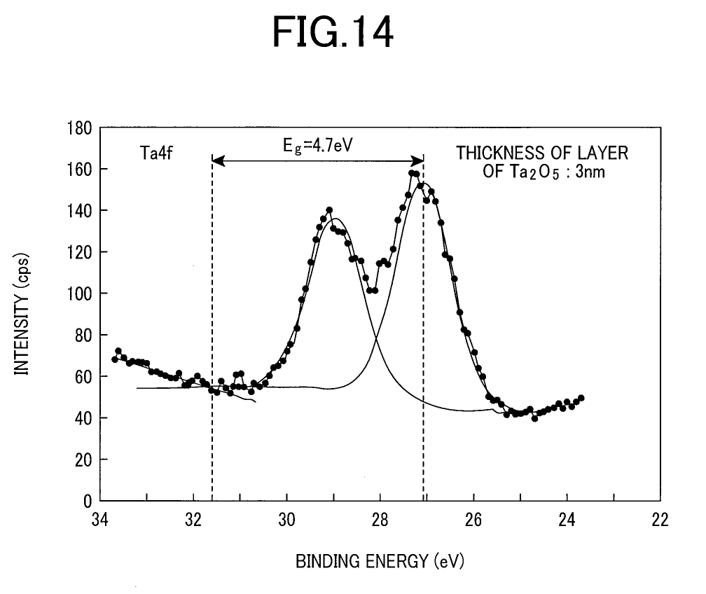

Then, FIG. 14 shows the waveform for the Ta4f peak attributable to tantalum pentoxide. Based on the energy difference between the peak energy of Ta4f and rising of the loss peak, the band gap of tantalum pentoxide was derived as 4.7 eV.

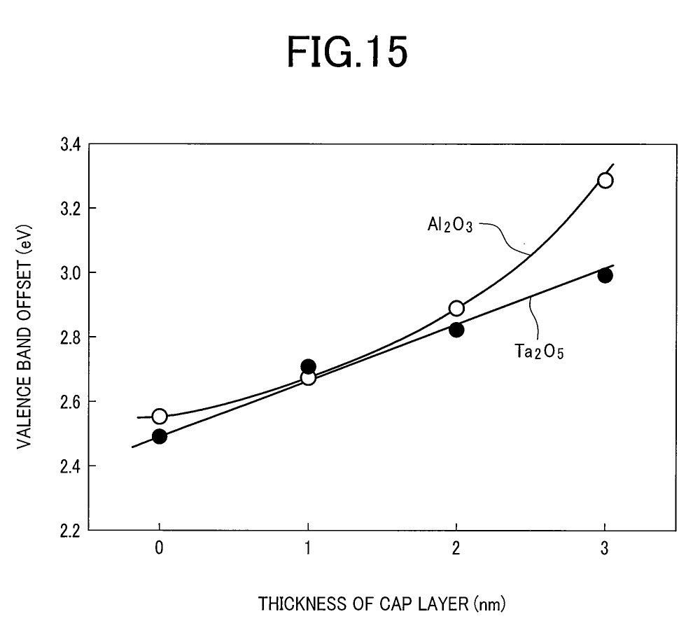

Then, FIG. 15 collectively shows the energy at the upper end of the valence band of the insulation layer determined from the valence band waveform obtained from a specimen with insertion of tantalum pentoxide and a specimen with insertion of alumina to the cap insulation layer shown in FIG. 11. As the layer thickness of tantalum pentoxide and alumina increases, the value of the valence band offset increases gradually. This is regarded as the way of change for the value of the valence band offset when ruthenium and hafnium dioxide are stacked with a sufficiently large layer thickness. It is considered that when the layer thickness of the cap insulation layer is made to about 3 nm, a band structure approximate to the value of the bulk of the cap insulation layer material is formed. In particular, when alumina is inserted, the amount of increase of the valence band offset is large. This is considered to be attributable to that the valence band offset of alumina is also larger compared with tantalum pentoxide since the valance band width of alumina is relatively as large as 6.6 eV.

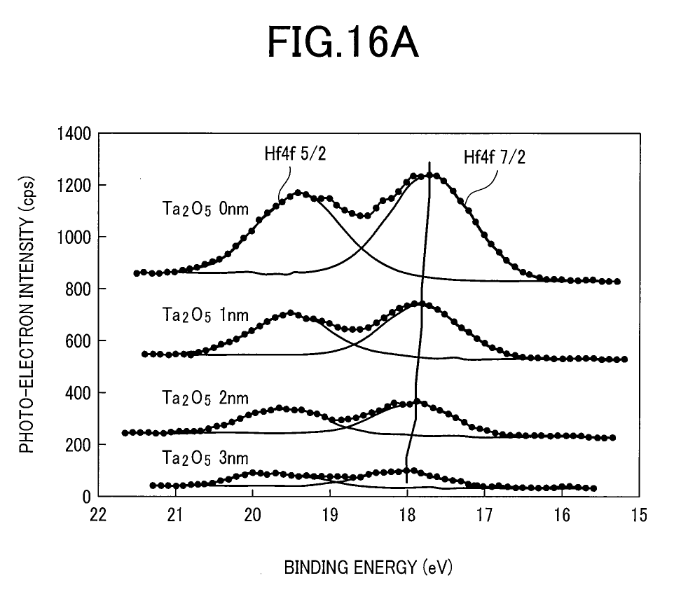

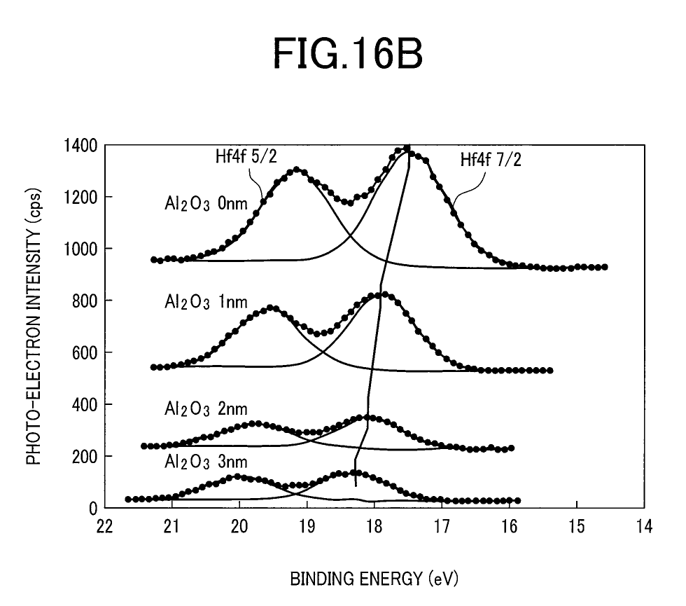

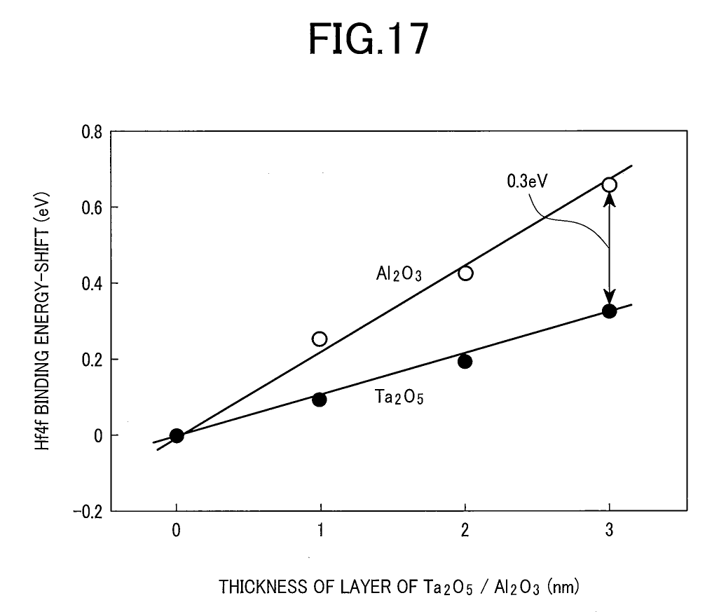

Then, waveforms of Hf4f peaks when tantalum pentoxide and alumina are inserted by from 0 nm to 3 nm as the cap insulation layer are shown in FIG. 16A and FIG. 16B respectively. It can be seen from the result that the peak energy for Hf4f is shifted toward the high energy side as layer thickness increases for each of the cap insulation layers. FIG. 17 collectively shows the shift amount of the peak energy. The peak shift of Hf4f is generated substantially linearly relative to the increase of the physical thickness of the cap insulation layer when tantalum pentoxide is inserted and when inserting alumina is inserted. A shift of about 0.3 eV was observed in the case of inserting tantalum pentoxide by 3 nm to the cap layer and the shift of about 0.6 eV was observed in the case of inserting alumina by 3 nm to the cap insulation layer. This energy shift means that the band of hafnium dioxide on the side nearer to ruthenium is lowered by as much as the energy shift relative to the Fermi energy. Accordingly, it has been found that when tantalum pentoxide is inserted by 3 nm to the cap insulation layer, the barrier height of hafnium dioxide on the side of ruthenium can be made higher by 0.3 eV compared with the case of inserting alumina by 3 nm.

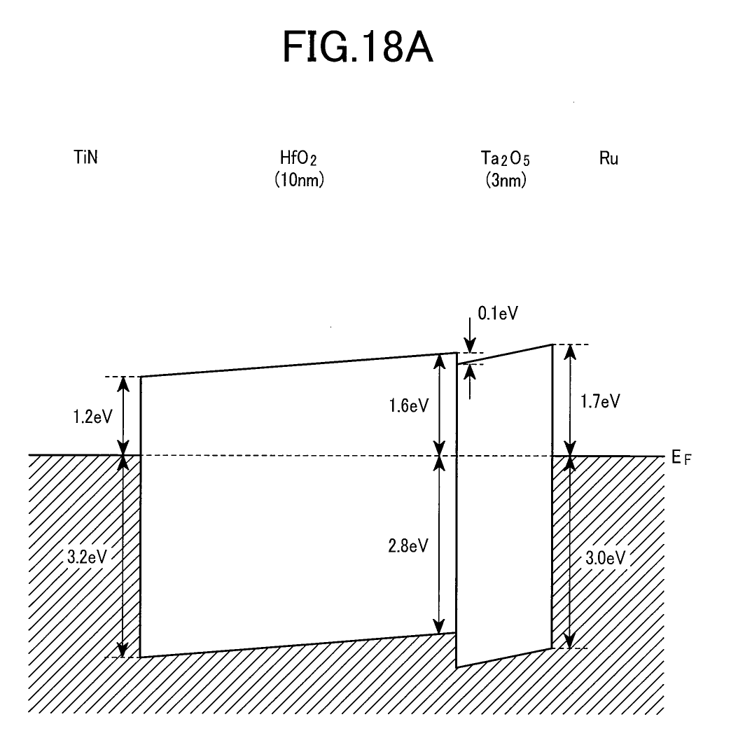

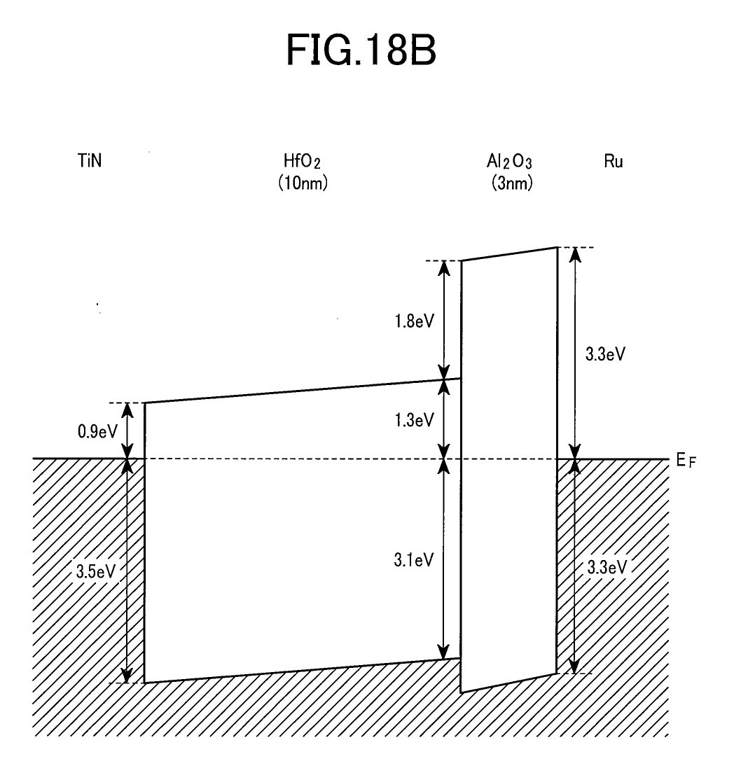

Assuming the work function of ruthenium as 4.8 eV and the work function of titanium nitride as 4.2 eV, the band structure of inserting tantalum pentoxide and alumina each by 3 nm as the cap insulation layer can be shown as in FIG. 18A and FIG. 18B respectively. As described previously, the barrier height of hafnium dioxide has a great contribution to the leak current. As the barrier height is higher, the leak current can be decreased more. Considering the cap insulation layer in view of the above, it is considered that the barrier height of hafnium dioxide can be made higher in the case of using tantalum pentoxide than in the case of using alumina for the cap insulation layer and this is effective for the decrease of the leak current.

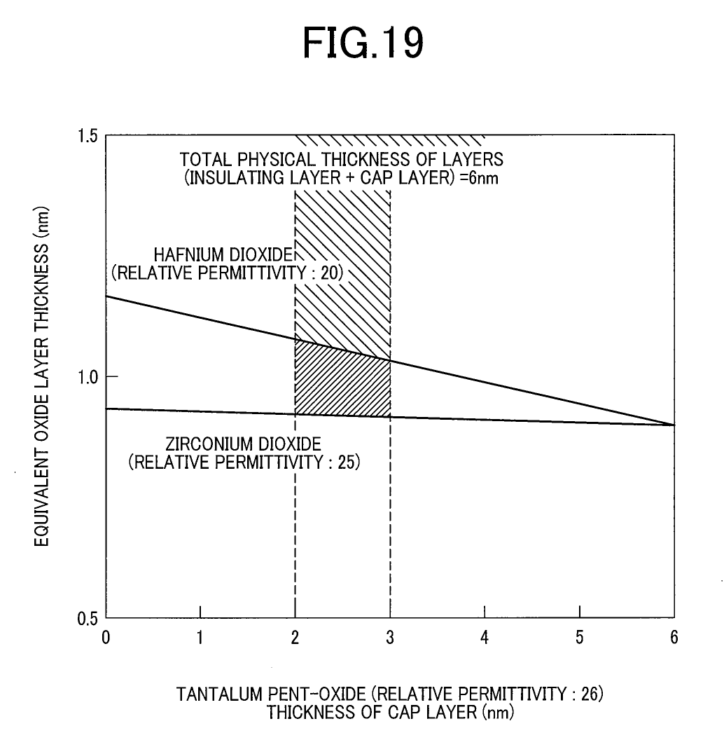

FIG. 19 shows a relation between the thickness of the cap insulation layer and the obtained equivalent oxide layer thickness. The abscissa expresses the physical thickness of the cap insulation layer of the tantalum pentoxide assuming the relative permittivity as 25, and the ordinate expresses the equivalent oxide layer thickness where the physical thickness of the insulation layer described in the graph together with the physical layer thickness of the insulation layer of tantalum pentoxide are defined as a minimum 6 nm required for suppressing the direct tunneling current. Further, black circles in the graph show the obtainable equivalent oxide layer thickness when the thickness of the cap insulation layer and the insulation layer is 2 nm or more at the lowest which forms a uniform layer respectively. When hafnium dioxide having a relative permittivity of 20 is used for the insulation layer, the equivalent oxide layer thickness of 1.2 nm or less can be formed. In particular, it has been found that a capacitor with the direct tunneling leakage current suppressed can be prepared at the equivalent oxide layer thickness of 1.2 nm or less when applying tantalum pentoxide by 2 nm to the cap insulation layer. When zirconium oxide having a relative permittivity of 25 is used for the insulation layer, a capacitor with an equivalent oxide layer thickness of 1.0 nm or less can be prepared in the same manner. Also even if tantalum pentoxide is used for the cap layer, the limit for film thickness reduction is substantially identical. That is, since tantalum pentoxide has a higher permittivity than hafnium dioxide or zirconium dioxide, the limit for film thickness reduction is not influenced even by the insertion of the cap layer. That is, it has been found that application of the cap layer comprising a material having a permittivity higher than that of the capacitor insulation layer is extremely effective since the capacitor can be formed with no increase in the equivalent oxide layer thickness or with no loss of the capacitance even when both of them are stacked such that the sum for the physical thickness of layer is identical.

From the foregoing result, it has been found that tantalum pentoxide is more desirable compared with alumina as the existent material for the material of the cap insulation layer. The cap insulation layer has to be a continuous layer since the cap insulation layer is provided for preventing diffusion. That is, the cap insulation layer has only to be formed at a minimum layer thickness as the continuous layer. It is actually 2 nm or more. Further, in the same manner, the thickness for the insulation layer also has to be 2 nm or more in order to form a continuous layer.

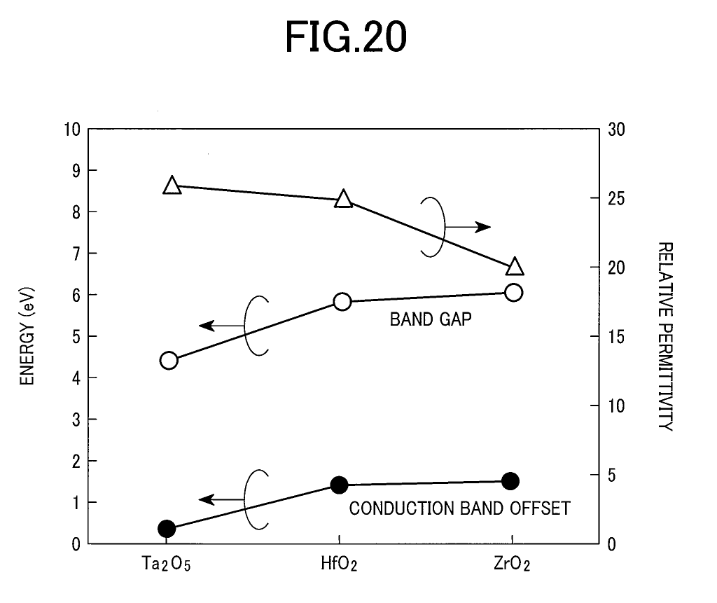

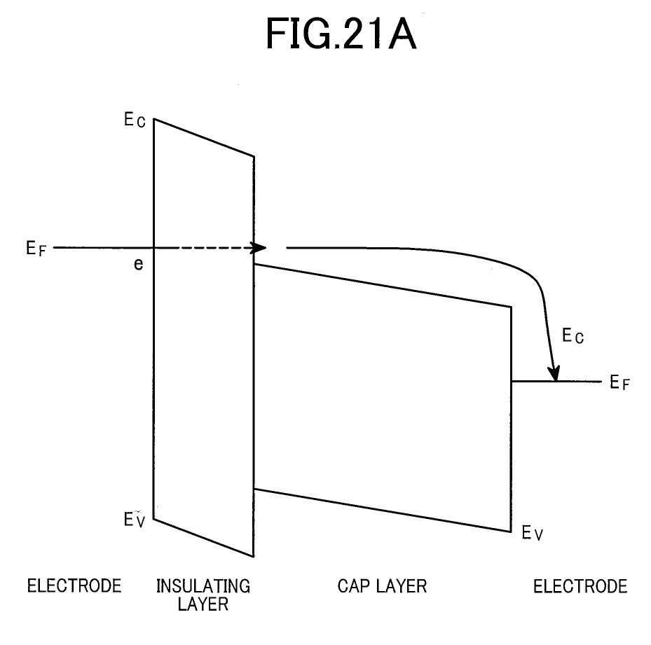

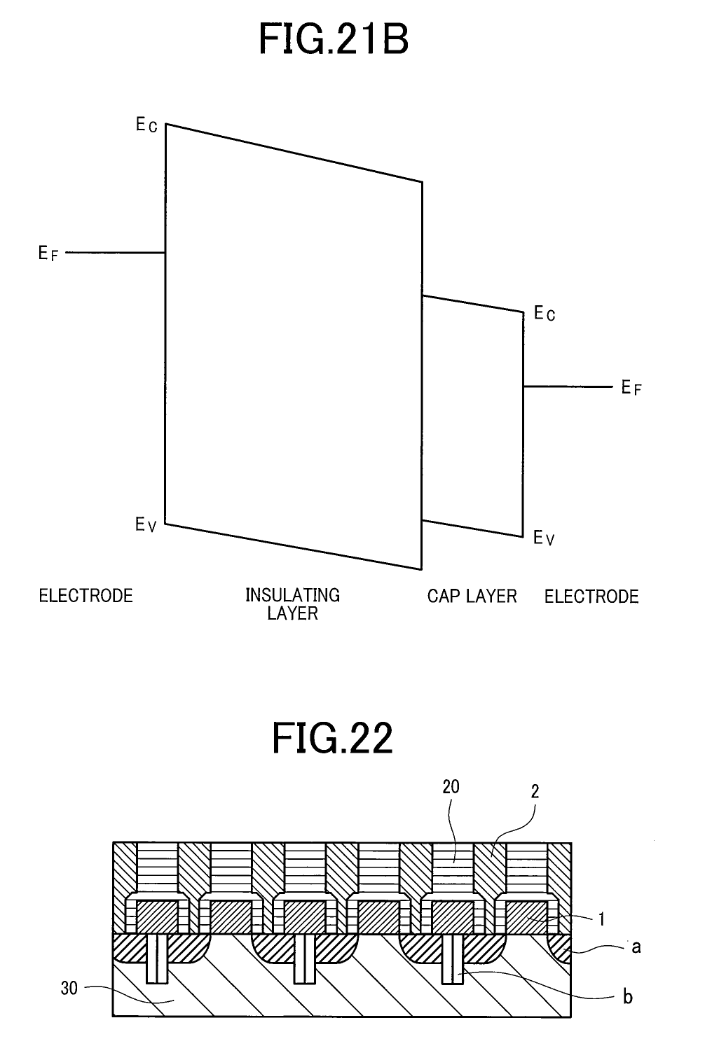

FIG. 20 shows values for band gap, the conduction band offset amount, and the relative permittivity for some of materials mentioned as candidates for the insulation layer and the cap insulation layer. Generally, the band gap of a material for the insulation layer is used as the index showing the insulation property of the insulation layer. The band gap of tantalum pentoxide is smaller compared with hafnium dioxide or zirconium dioxide. However, when a capacitor is prepared and carriers are electrons, conduction band offset has a relation with a conduction mechanism (Fowler-Nordheim tunneling current, etc.) each of the carriers in the insulation layer. Since these values act as a barrier for the carriers, it is considered that the insulation performance is higher as the value is larger. In view of FIG. 20, it can be seen that tantalum pentoxide used for the cap insulation layer has a smaller conduction band offset amount compared with hafnium dioxide or zirconium dioxide as the insulation layer material. In view of the facts described above and estimation, hafnium dioxide or zirconium dioxide as the insulation layer is effective for the suppression of the Fowler-Nordheim tunneling current when the cap insulation layer of tantalum pentoxide and the insulation layer are stacked. FIG. 21A and FIG. 21B show band structures of capacitors in which electrodes, an insulation layer, and a cap insulation layer of smaller conduction band offset than the insulation layer are stacked when a positive voltage is applied to the electrode on the side in contact with the cap insulation layer. As shown in FIG. 21A, in the case where the thickness of layer of the insulation layer material with large conduction band offset amount such as hafnium dioxide or zirconium dioxide is thin, electrons in the electrode pass through the insulation layer by the tunneling effect upon applying the voltage to the electrode, move in the conduction band of the cap insulation layer with a small conduction band offset amount and reach another electrode to possibly increase the leak current as shown in FIG. 21. On the other hand, in the case where the physical thickness of the insulation layer having a large conduction band offset amount is large as shown in FIG. 21B, it is considered that the F-N tunneling leakage current flowing from the electrode through the insulation layer into the cap insulation layer is suppressed and the leak current of the capacitor is also suppressed. That is, a different insulation layer material is stacked as the capacitor insulation layer, the thickness of the insulation layer having a large valence band offset amount should be increased in a range of 6 nm or less where the direct tunneling current is remarkable. It has been described previously that the range for the thickness of the cap insulation layer is 2 nm or more and 3 nm or less. In the case where the conduction band offset amount of the cap insulation layer material is smaller than the conduction band offset amount of the insulation layer material, it is desired that the thickness of the cap insulation layer be thinner than that of the insulation layer because the leak current can be suppressed.

Comparison is to be made with the structure of Ru/Ta₂O₅/HfO₂/TiN shown in the Non-Patent Document 1. While this embodiment and the Non-Patent Document 1 have similarity in view of the stacked form, the concept of the invention is distinctly different between them. The Non-Patent Document 1, intends to use Ta₂O₅ of higher permittivity and ensure the thickness of Ta₂O₅ for increasing the permittivity of the capacitor insulator. That is, the Non-Patent Document 1 intends for double layer dielectric (Ta₂O₅/HfO₂ double dielectric) of Ta₂O₅/HfO₂. On the other hand, in the present invention, it is intended to decrease the leak current by replacing the upper electrode TiN of the TiN/HfO₂/TiN structure with Ru. In this case, it is intended to find the instability at the boundary between HfO₂ and Ru, analyze the factor, and inhibit element diffusion at the boundary between HfO₂ and Ru. As a result, Ta₂O₅ has been selected in view of other factors, for example, the conduction band offset amount in the band structure.

Accordingly, as has been described above, a minimum layer thickness suffices to form a continuous layer. For example, if a layer is formed by the atomic layer deposition, a continuous layer is formed through film formation by the number of cycles corresponding to 2 nm or more.

Embodiment 1 has been described above specifically and the outline for Embodiment 1 is summarized as below. That is, it has been found that when the upper electrode of ruthenium is stacked directly on hafnium dioxide, ruthenium diffuses into hafnium dioxide. To suppress diffusion of ruthenium into hafnium dioxide, tantalum pentoxide forming a boundary with each of materials in which the element profile is steep along the direction of the depth is inserted. Tantalum pentoxide has a higher permittivity compared with alumina as an existent material for the cap insulation layer and can suppress increase in the equivalent oxide layer thickness by insertion. Further, lowering of the conduction band offset of hafnium dioxide by tantalum pentoxide of the cap insulation layer can be suppressed more compared with a case of using alumina for the cap insulation layer and this is advantageous also in view of suppressing for the leak current.

Further, in the invention, identical effects can be obtained also by using ruthenium oxide in addition to ruthenium for the first electrode, yttrium-added hafnium oxide and zirconium oxide in addition to hafnium dioxide for the capacitor insulation layer, and titanium nitride, titanium, tantalum nitride, tantalum, tungsten nitride, tungsten, phosphorus-doped polysilicon, gold, silver, copper, and platinum for the second electrode. Further, preferred addition amount of yttrium to hafnium oxide is within a range about from 10 at % to 20 at %. This material is preferred in view of the permittivity.

### <Example of Manufacturing Method>

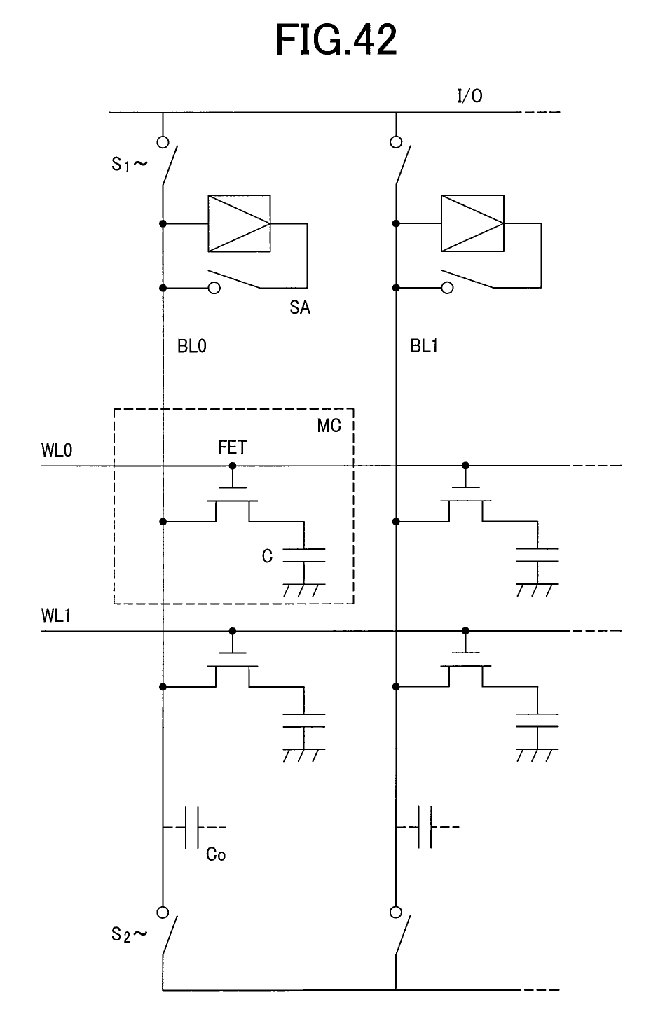

FIG. 42 is an equivalent circuit diagram for a DRAM in Embodiment 1. Since the equivalent circuit per se is an usual circuit, detailed descriptions are to be omitted and the outline is as described below. A DRAM array includes a plurality of word lines WL (WL0, WL1, - - - ) and a plurality of bit lines BL (BL0, BL1, - - - ) arranged in a matrix and a plurality of memory cells (MC) arranged at the intersections thereof. One memory cell comprises one capacitor C and one memory cell selecting FET connected in series therewith. One of the source and the drain of the memory cell selecting FET is electrically connected with the capacitor C and the other is connected electrically with the bit line BL. One end of the word line WL is connected with a word driver (not illustrated) and one end of the bit line BL is connected with a sense amplifier SA. There are shown a common data output line I/O, a data line parasitic capacitance Co, column selection switch S1, and a precharge switch S2.

A method of manufacturing a DRAM memory capacitor having the capacitor according to the invention is to be described. This embodiment is an example of an information storing capacitor in which the second electrode, an insulation layer for use in the capacitor deposited on the second electrode, the cap insulation layer deposited on the insulation layer for use in the capacitor, and a first electrode deposited on the cap insulation layer are formed on the inner surface in the hole of the insulation layer.

A bit line 1 is formed on the memory cell selecting transistor formed by a usual method, and a polysilicon plug 2 for electrically connecting the selection transistor and the capacitor is formed. FIG. 22 is a cross sectional view for a main portion of the memory. In FIG. 22, reference character a denotes a diffusion layer of the transistor. The diffusion layer a is formed by implanting a dopant to a silicon substrate 30 as an n-type and p-type by a usual method. In the drawing, reference character b shows isolation, which electrically isolating adjacent transistors from each other. In the drawing, reference numeral 20 denotes an insulation layer. Since the invention concerns the structure of a memory capacitance portion connected to the transistor of the memory portion, the drawing for this example illustrates only the portion, and a semiconductor device portion to be formed above the semiconductor substrate is not illustrated and not described specifically in the following drawings.

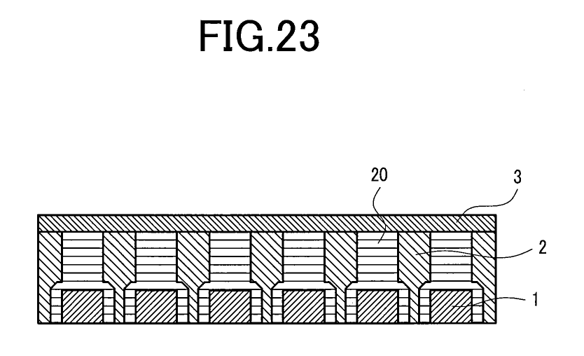

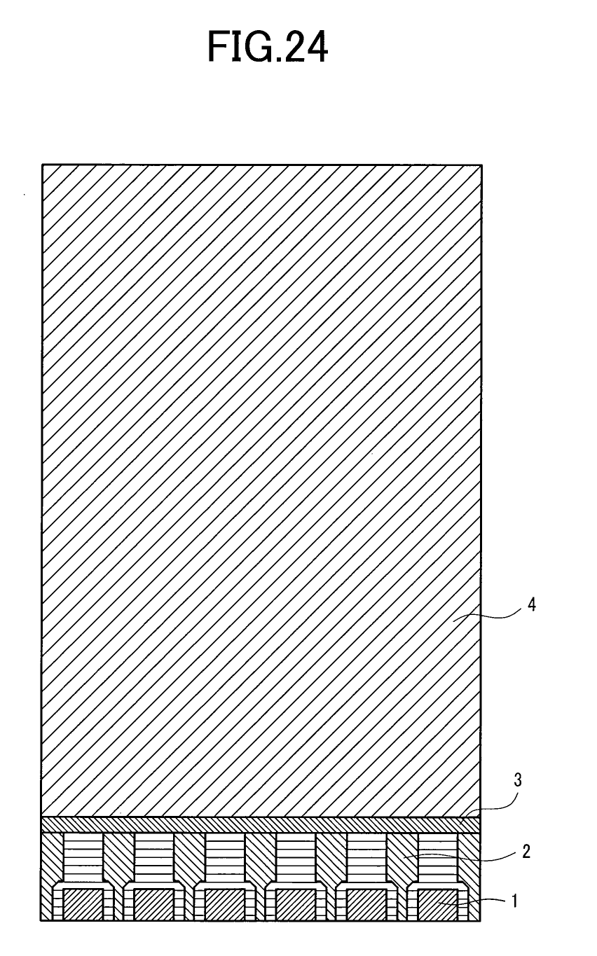

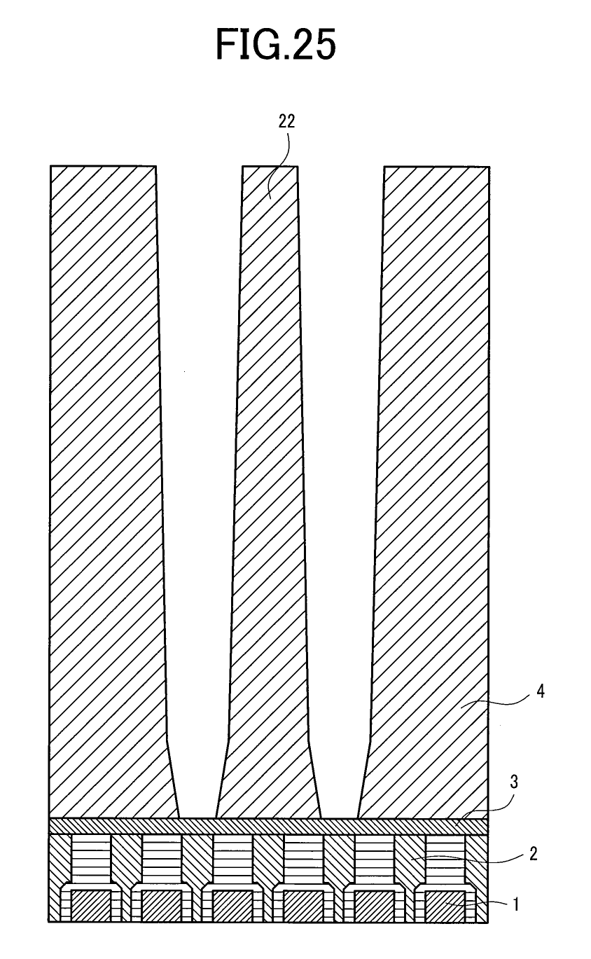

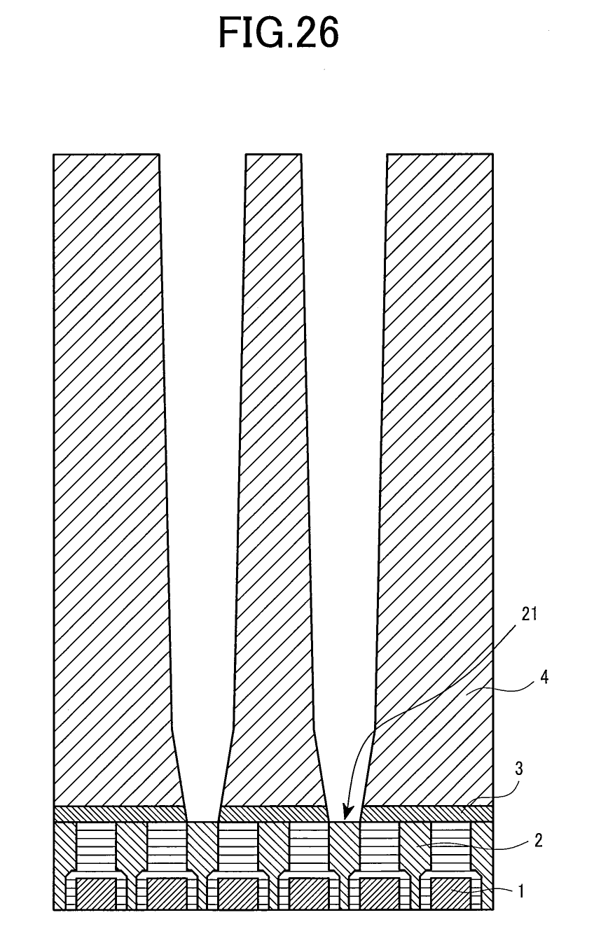

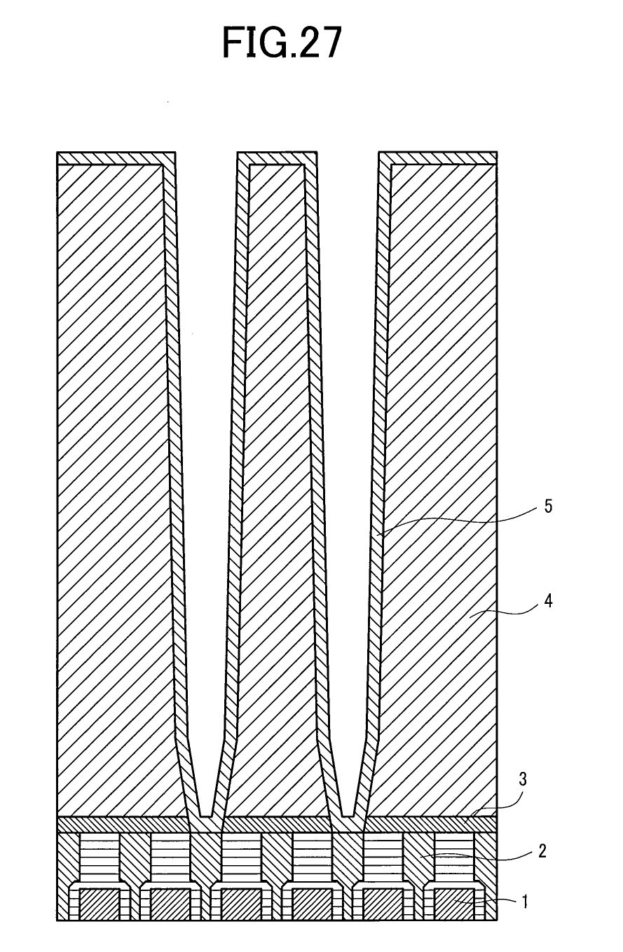

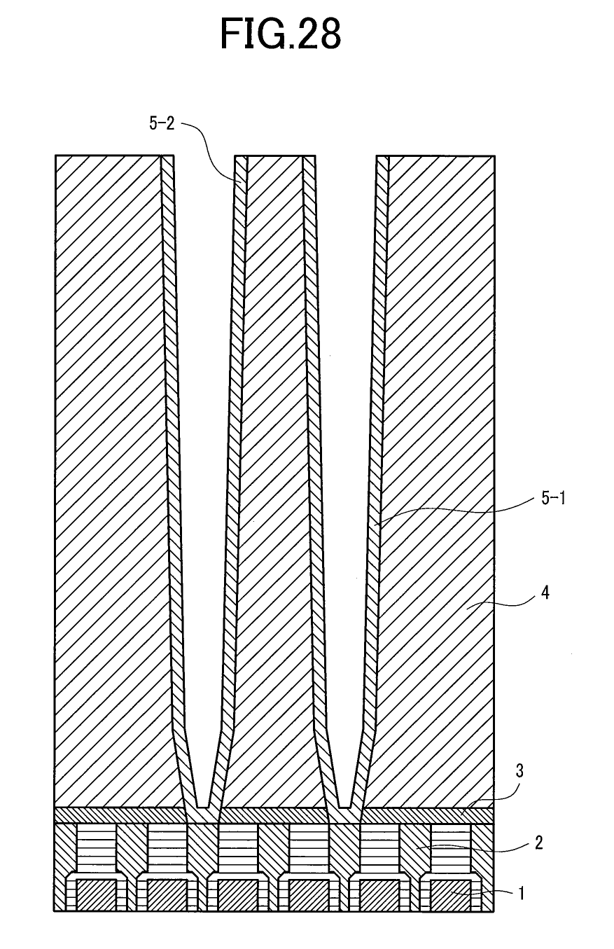

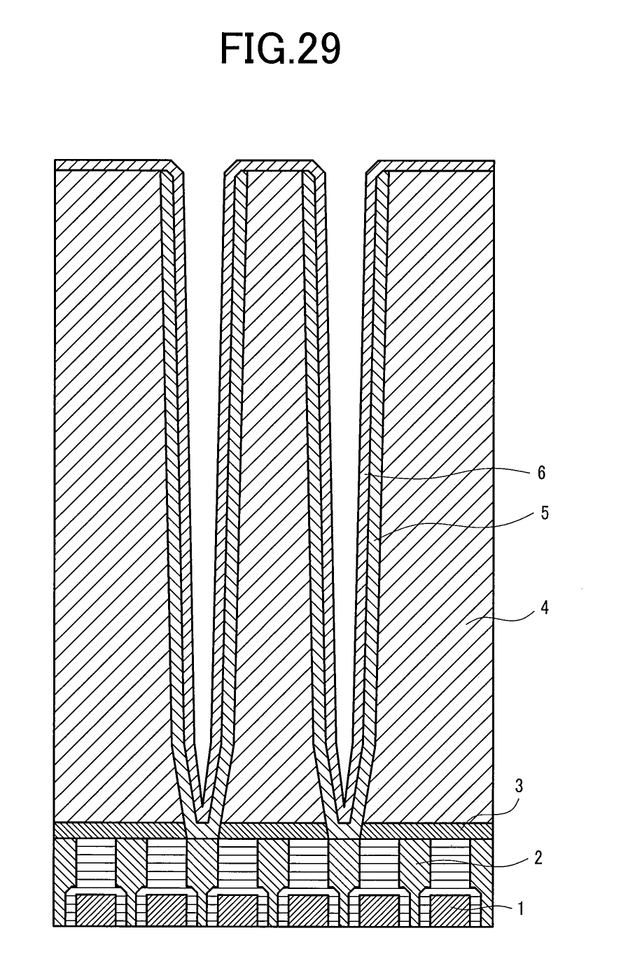

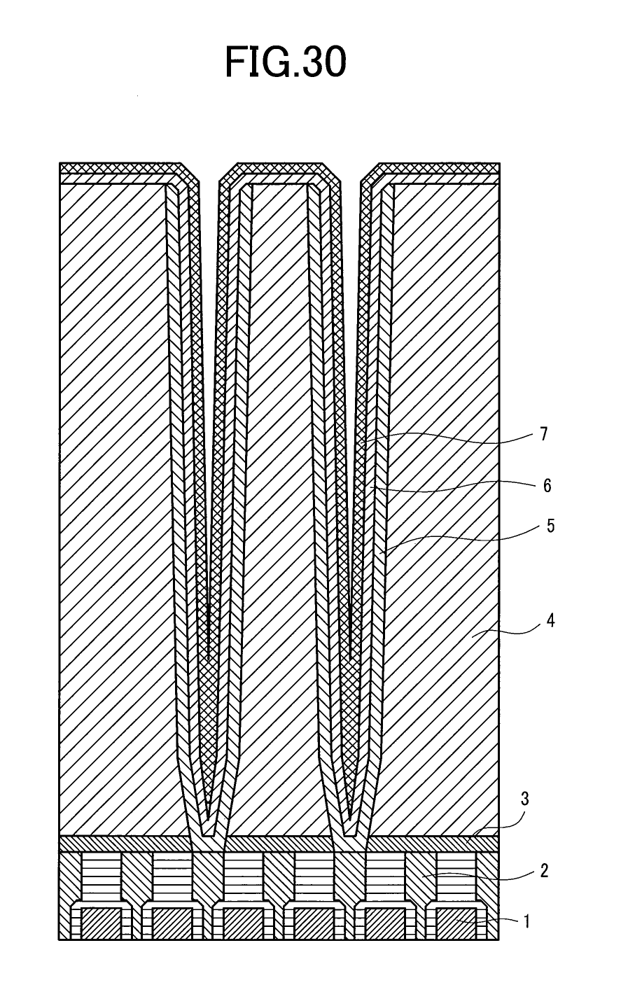

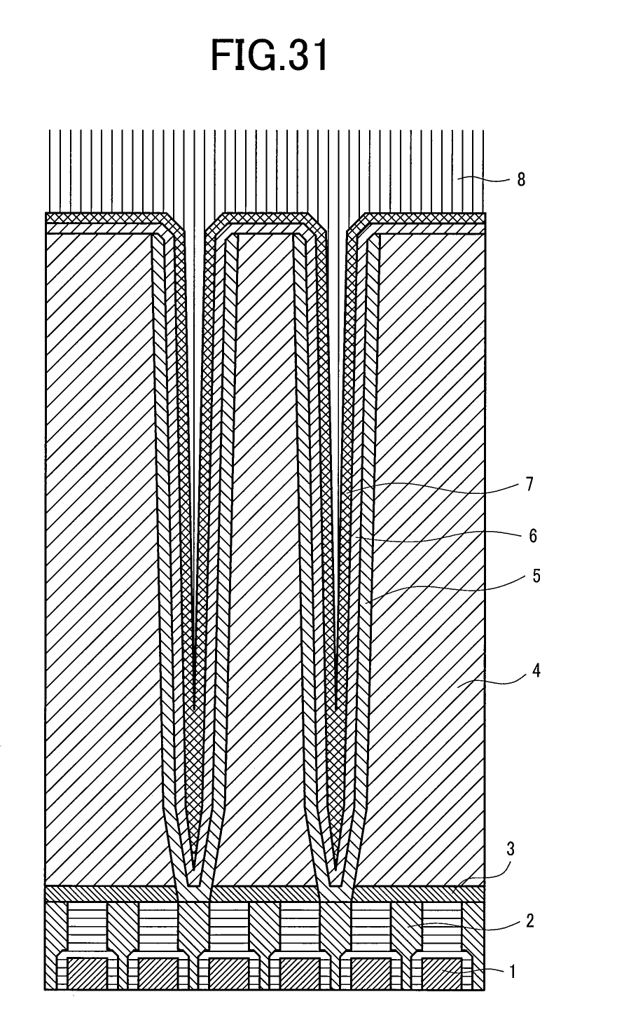

Above them, a silicon nitride layer 3 of about 100 nm thickness is deposited as shown in FIG. 23 by chemical vapor deposition. The silicon nitride layer functions as an etching stopper in the following fabrication. Then, as shown in FIG. 24, a silicon oxide layer 4 is formed by using tetraethoxysilane as a starting material on the silicon nitride layer 3. The silicon nitride layer 4 is fabricated into a columnar silicon oxide layer 22. FIG. 25 is a cross sectional view for the state. For the fabrication, a dry etching is applied by using, as a mask, a material having a high etching selectivity relative to the silicon oxide layer such as a photoresist layer, polysilicon, tungsten, or carbon. Further, dry etching for the silicon nitride film 3 is conducted successively to form a trench 21 for use in the lower electrode above the polysilicon plug 2 as shown in FIG. 26. Further, as shown in FIG. 27, a titanium nitride film 5 is stacked by 35 nm as a lower electrode material by chemical vapor deposition or atomic layer deposition. As the material for the lower electrode, any material such as tantalum nitride, tantalum, tungsten nitride, tungsten, phosphorus-doped polysilicon, gold, silver, copper, or platinum which forms a steep boundary when stacked with the insulation layer such as of hafnium oxide can be applied. Then, the titanium nitride film 5 is separated on every bit 5-1, 5-2, by a usual etching back technique using a photoresist layer as shown in FIG. 28. Upon inter-apparatus transportation, titanium oxide is formed by about 2 nm on the surface of the titanium nitride 5. This titanium oxide is removed by wet etching using, for example, hydrofluoric acid. Successively, as shown in FIG. 29, hafnium dioxide 6 is deposited as an insulation layer by chemical vapor deposition or atomic layer deposition. In this case, as a starting material for depositing by atomic layer deposition, TEMAH (tetraethyl methyl amide hafnium) and ozone are used. The insulation layer may also be zirconium oxide. The hafnium dioxide film is a capacitor insulation layer. Then, as shown in FIG. 30, tantalum oxide 7 is deposited as a cap insulation layer to 2 nm or more and 4 nm or less by chemical vapor deposition or atomic layer deposition. The cap insulation layer may also be a niobium oxide film. Then, as shown in FIG. 31, ruthenium 8 for the upper electrode is film formation by chemical vapor deposition or atomic layer deposition. For the upper electrode material, ruthenium oxide may also be applied.

### Embodiment 2

It is considered that the result shown in Embodiment 1 may be obtained also in the case of reversing the relation of the capacitor up side down. That is, ruthenium is used for the lower electrode and hafnium dioxide is used as the insulation layer. Since ruthenium diffuses into hafnium dioxide when stacking ruthenium and hafnium dioxide, tantalum pentoxide is inserted as the cap insulation layer to the boundary. Finally, titanium nitride is formed as the upper electrode. Since also the capacitor of this structure results in a problem shown in Embodiment 1 that ruthenium diffuses into hafnium dioxide to increase scattering of the leak current density, the cap insulation layer of tantalum pentoxide is inserted to the boundary to solve the problem and the reaction can be suppressed.

A method of manufacturing a DRAM memory capacitor having a capacitor suitable to a second embodiment is to be described. Also in this example, since the invention concerns a structure of a memory capacitor portion connected to the transistor of the memory section, drawing illustrates only the portion and illustration and detailed description are to be omitted for the semiconductor device portion formed above the semiconductor substrate.

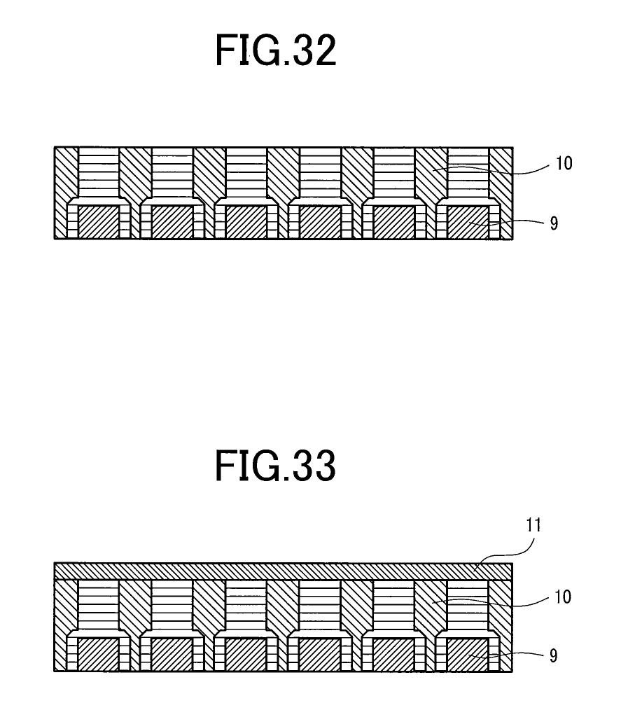

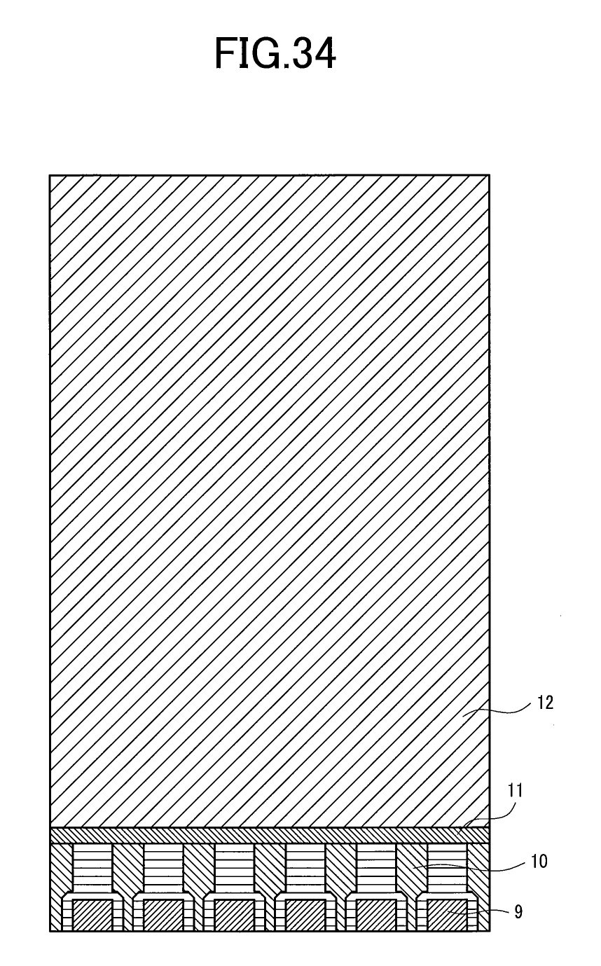

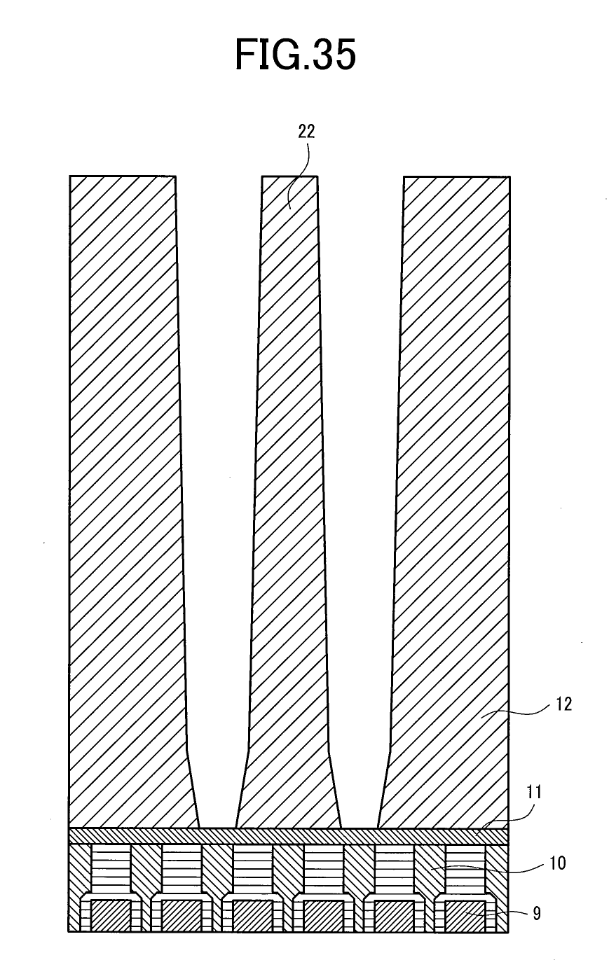

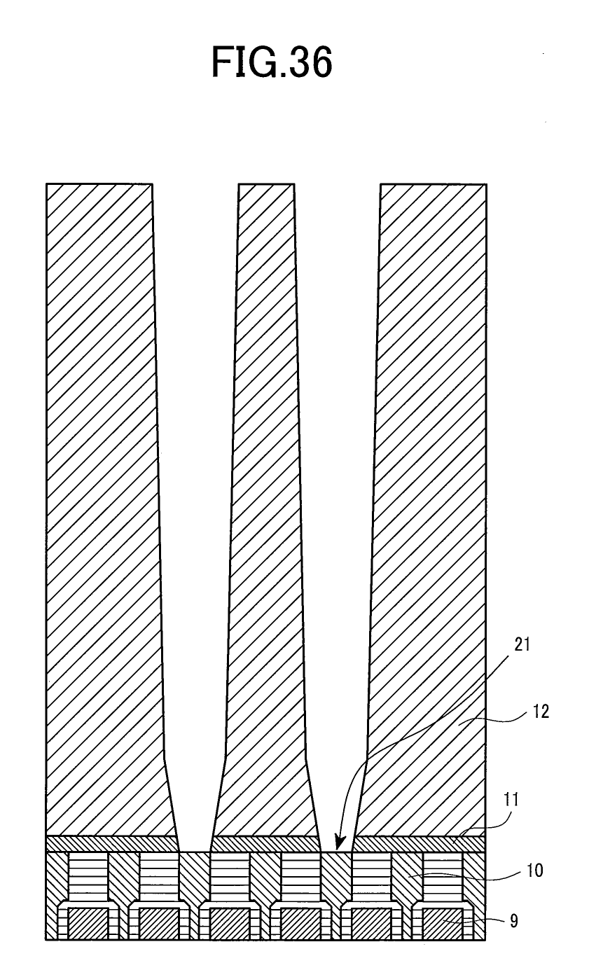

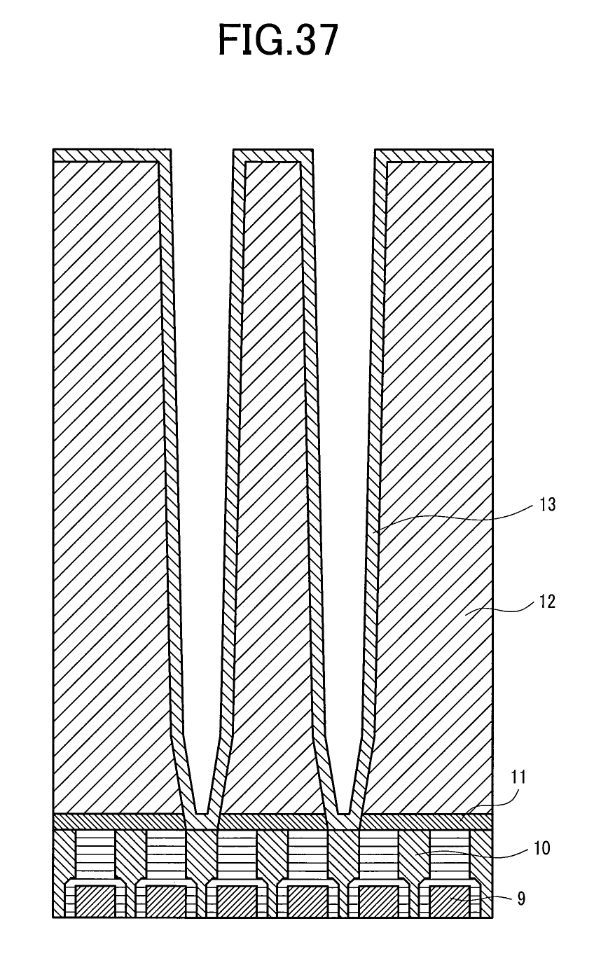

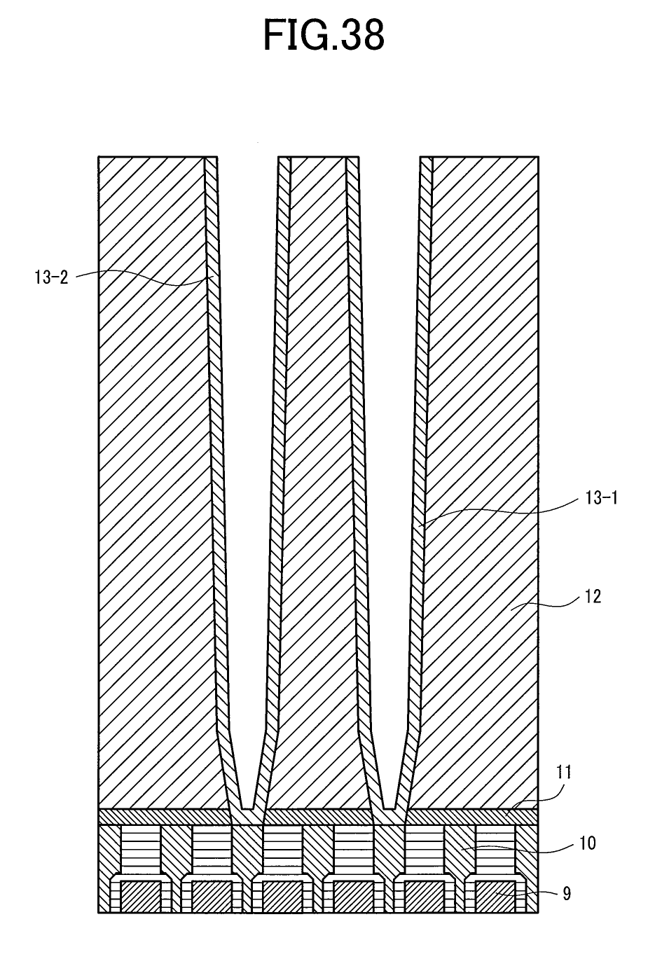

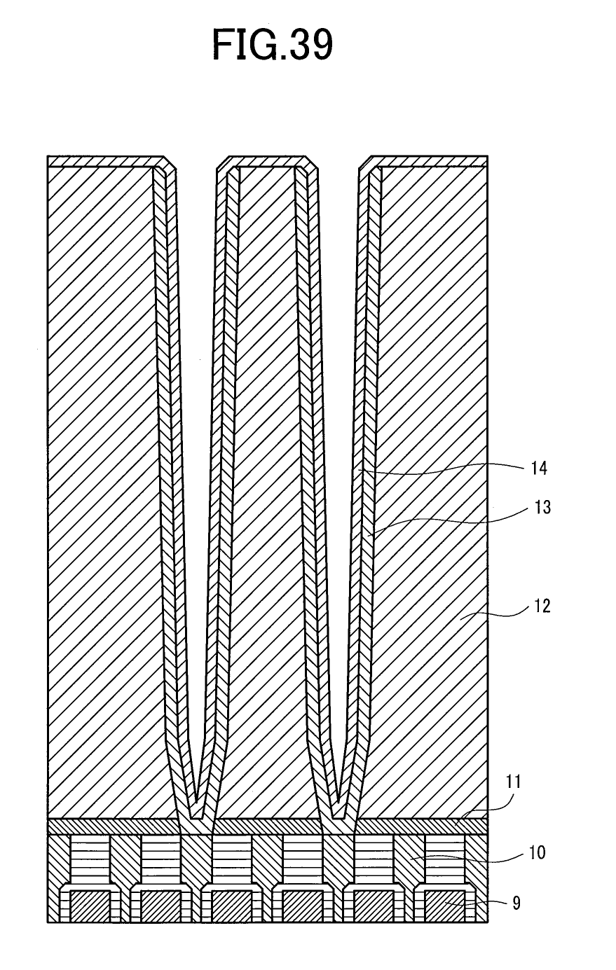

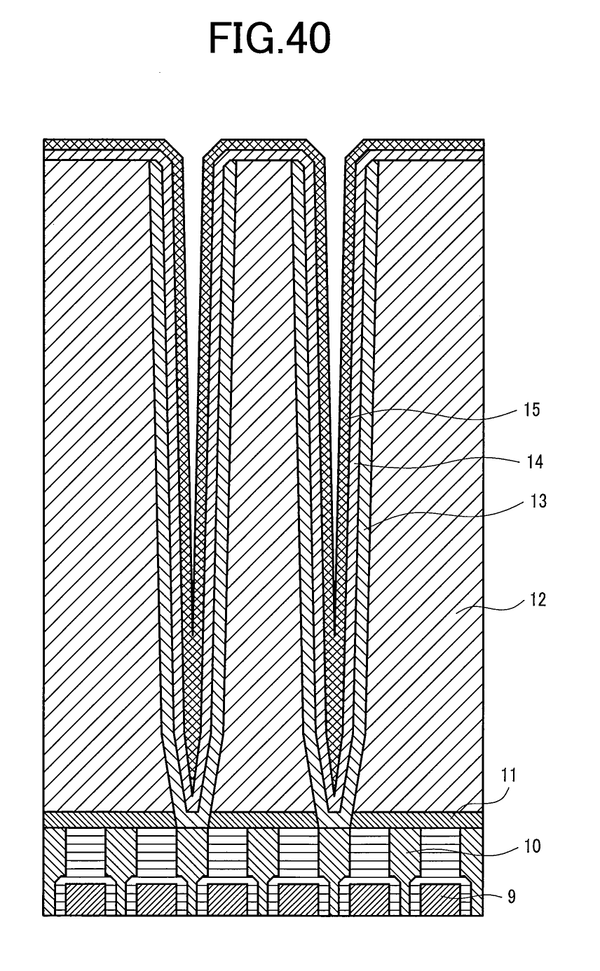

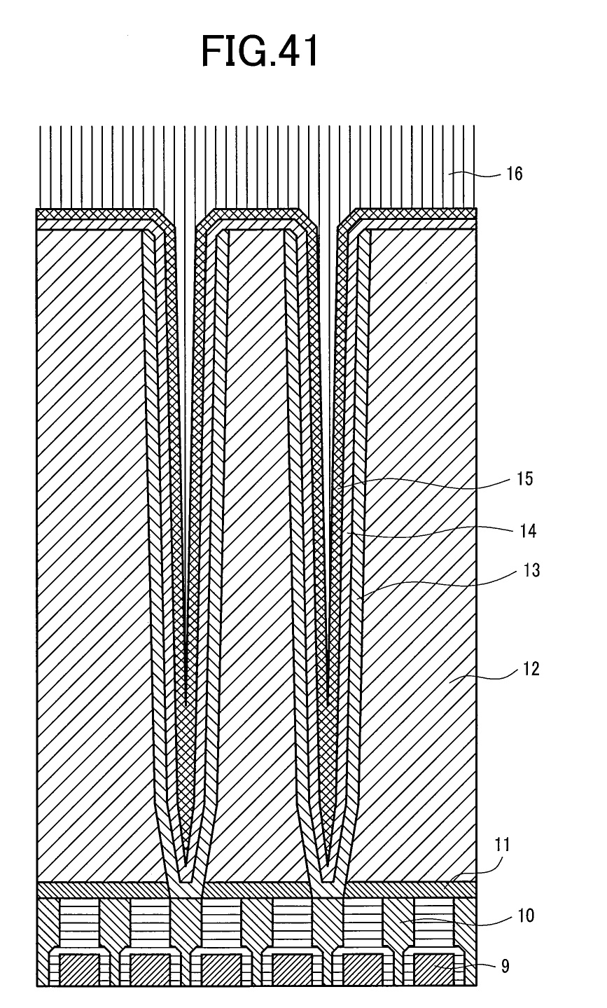

As shown in FIG. 32, bit lines 9 are formed above the memory cell selecting transistors formed by a usual method, and polysilicon plugs 10 electrically connecting the select transistors and the capacitors are formed. As shown in FIG. 33, a silicon nitride film 11 of about 100 nm layer thickness is deposited thereon by chemical vapor deposition as an etching stopper upon fabrication of the silicon nitride film. Then, as shown in FIG. 34, a silicon oxide layer 12 using tetraethoxysilane as a starting material is formed on the silicon nitride layer 11. The silicon oxide layer 12 is fabricated into columnar silicon oxide 22 as shown in FIG. 35. For the fabrication, dry etching is used using, as a mask, a material such as a photoresist film, polysilicon, tungsten or carbon having a high etching selectivity relative to the silicon oxide layer. Further, dry etching is conducted continuously for the silicon nitride layer 11 and trenches 21 for the lower electrode are formed above the polysilicon plugs as shown in FIG. 36. Further, as shown in FIG. 37, as the material for the lower electrode, a ruthenium layer 13 was deposited to 20 nm by chemical vapor deposition or atomic layer deposition. For the lower electrode material, ruthenium oxide having a similar property can also be applied. Then, as shown in FIG. 38, the ruthenium layer 13 is separated on every bit 13-1, 13-2, by an etching back technique using a photoresist film. During inter-apparatus transportation, ruthenium oxide is formed by about 1 nm on the surface of ruthenium. This ruthenium oxide may also be removed by wet etching using, for example, hydrofluoric acid. Successively, as shown in FIG. 39, tantalum oxide is deposited as the cap insulation layer 14 to 2 nm or more and 5 nm or less by chemical vapor deposition or atomic layer deposition. The cap insulation layer may also be formed of niobium oxide. Then, as shown in FIG. 40, hafnium dioxide 15 is deposited as an insulation layer by chemical vapor deposition or atomic layer deposition. As the starting material upon film formation by atomic layer deposition, TEMAH (tetra-ethyl-methyl-amide-hafnium) and ozone are used. The insulation layer may be formed of zirconium oxide having similar property. Then, as shown in FIG. 41, titanium nitride 16 for the upper electrode is deposited by chemical vapor deposition or atomic layer deposition. As the material for the upper electrode, any material such as titanium, tantalum nitride, tantalum, tungsten nitride, tungsten, phosphorus-doped polysilicon, gold, silver, copper and platinum that form a steep boundary with the insulation layer is applicable.

Identical device characteristics with those in Embodiment 1 are shown also in this structure.

References in the appended drawings will be described briefly.
1: bit line
2: plug
3: silicon nitride
4: silicon oxide
5: lower electrode (for example, titanium nitride)
6: capacitor insulation layer (for example, hafnium oxide)
7: cap insulation layer (for example, tantalum oxide)
8: upper electrode (for example, ruthenium)
9: bit line
10: plug
11: silicon nitride
12: silicon oxide
13: lower electrode (for example, ruthenium)
14: cap insulation layer (for example, tantalum oxide)
15: capacitor insulation layer (for example, hafnium oxide)
16: upper electrode (for example, titanium nitride)
20: insulation layer
21: trench
22: columnar silicon oxide layer
5-1, 5-2: titanium nitride layer separated on every bit
13-1, 13-2: ruthenium layer separated on every bit
30: silicon substrate
WL0, WL1: word line
BL0, BL2: bit line
MC: memory cell
C: capacitor
FET: field effect transistor
C₀: parasitic capacitance
S1: column selection switch
S2: precharge switch

What is claimed is:

1. A semiconductor integrated circuit device, comprising, above a semiconductor substrate:
a plurality of word lines;
a plurality of bit lines; and
memory cells each comprising a memory selecting transistor disposed at a predetermined intersection between the plurality of word lines and the plurality of bit lines, and an information storing capacitor connected electrically in series with the memory selecting transistor;
wherein:
the information storing capacitor has a second electrode, a capacitor insulation layer deposited on the second electrode, a cap insulation layer deposited on the cap capacitor insulation layer, and a first electrode deposited on the cap insulation layer,
the first electrode is at least one member selected from ruthenium and ruthenium oxide,
the capacitor insulation layer is at least one member selected from the group consisting of hafnium dioxide, yttrium-added hafnium dioxide, and zirconium oxide,
the cap insulation layer is at least one member selected from tantalum oxide and niobium oxide having a higher permittivity than the cap insulation layer,
the second electrode is at least one element selected from the group consisting of titanium nitride, titanium, tantalum nitride, tantalum, tungsten nitride, tungsten, phosphorus-doped polysilicon, gold, silver, copper, and platinum, and
the cap insulation layer constitutes a continuous layer and has a thickness of 3 nm or less.

2. A semiconductor integrated circuit device according to claim 1, wherein the thickness of the cap insulation layer is 2 nm or more and 3 nm or less.

3. A semiconductor integrated circuit device according to claim 1, wherein the cap insulation layer has a smaller reduction in an amount of the conduction band offset of the insulation layer compared with a case of using alumina for the cap insulation layer by insertion between the insulation layer and the upper electrode.

4. A semiconductor integrated circuit device according to claim 1, wherein the information storing capacitor has the second electrode, the capacitor insulation layer deposited on the second electrode, the cap insulation layer deposited on the capacitor insulation layer, and a first electrode deposited on the cap insulation layer formed to the inner surface in the holes of the insulation layer.

5. A semiconductor integrated circuit device, comprising, above a semiconductor substrate:
a plurality of word lines;
a plurality of bit lines; and
memory cells each comprising a memory selecting transistor disposed at a predetermined intersection between the plurality of word lines and the plurality of bit lines, and an information storing capacitor connected electrically in series with the memory selecting transistor;
wherein:
the information storing capacitor has a second electrode, a cap insulation layer deposited on the second electrode, an capacitor insulation layer deposited on the cap insulation layer, and a first electrode deposited on the cap insulation layer,
the first electrode is at least one member selected from ruthenium and ruthenium oxide,
the capacitor insulation layer is at least one member selected from the group consisting of hafnium dioxide, yttrium-added hafnium dioxide, and zirconium oxide,
the cap insulation layer is at least one member selected from tantalum oxide and niobium oxide having a higher permittivity than the capacitor insulation layer,
the second electrode is at least one element selected from the group consisting of titanium nitride, titanium, tantalum nitride, tantalum, tungsten nitride, tungsten, phosphorus-doped polysilicon, gold, silver, copper, and platinum, and
the cap insulation layer constitutes a continuous layer and has a thickness of 3 nm or less.

6. A semiconductor integrated circuit device according to claim 5, wherein the thickness of the cap insulation layer is 2 nm or more and 3 nm or less.

7. A semiconductor integrated circuit device according to claim 5, wherein the cap insulation layer has a smaller reduction in an amount of the conduction band offset of the insulation layer compared with a case of using alumina for the cap insulation layer by insertion between the insulation layer and the upper electrode.

8. A semiconductor integrated circuit device according to claim 5, wherein the information storing capacitor has the second electrode, the cap insulation layer deposited on the second electrode, the capacitor insulation layer deposited on the cap insulation layer, and a first electrode deposited on the capacitor insulation layer formed to the inner surface in the holes of the insulation layer.
